(19) United States
(12) Patent Application Publication
(10) Pub. No.: US 2026/0047278 A1
(43) Pub. Date: Feb. 12, 2026

(54) DISPLAY DEVICE

(71) Applicant: LG Display Co., Ltd., Seoul (KR)

(72) Inventors: Wonrae KIM, Paju-si (KR); Seungbum LEE, Paju-si (KR); Sunwoo KIM, Paju-si (KR); Jiyoon CHOI, Paju-si (KR)

(73) Assignee: LG Display Co., Ltd., Seoul (KR)

(21) Appl. No.: 19/258,721

(22) Filed: Jul. 2, 2025

(30) Foreign Application Priority Data
Aug. 9, 2024 (KR) 10-2024-0106491

(51) Int. Cl. H10K 59/122; H10K 59/80

(52) U.S. Cl. CPC H10K 59/122; H10K 59/8792

(57) ABSTRACT

Discussed is a display device including a substrate having a display area including a plurality of sub-pixels including, and a non-display area around the display area, an anode electrode disposed in each of the plurality of sub-pixels on the substrate in the display area, a bank disposed on the anode electrode in the display area, located at a boundary between adjacent sub-pixels, and overlapping a periphery of an upper surface of the anode electrode, an organic layer disposed on the anode electrode and the bank in the display area and disposed across the plurality of sub-pixels, and a dam on the substrate in the non-display area, in which the dam includes a same material as the bank, and a surface unevenness is formed on an upper surface of the bank in the display area.

### CROSS-REFERENCE TO RELATED APPLICATION

The present application claims priority to Korean Patent Application No. 10-2024-0106491, filed in the Republic of Korea on Aug. 9, 2024, the entire contents of which is hereby expressly incorporated by reference into the present application.

### BACKGROUND OF THE DISCLOSURE

### Field

The present disclosure relates to a display device.

### Discussion of the Related Art

With advancements on how information is obtained lately, various demands for display devices for displaying images containing the information are increasing, and various types of display devices such as liquid crystal display (LCD) devices and organic light emitting diode (OLED) display devices are being utilized to better provide such information.

A display device includes a plurality of pixels and a plurality of switching elements for driving and controlling the pixels, and allows efficient display of information.

### SUMMARY OF THE DISCLOSURE

Embodiments of the present disclosure are directed to providing a display device in which it is possible to minimize a lateral leakage current between adjacent sub-pixels.

Embodiments of the present disclosure are also directed to providing a display device in which a bank can include a black-based material to absorb external light incident on a lower portion of the bank.

Embodiments of the present disclosure are also directed to providing a display device in which an organic layer is formed integrally across all of sub-pixels, but, by forming a surface unevenness on a surface of a bank, it is possible to minimize a lateral leakage current between adjacent sub-pixels.

Embodiments of the present disclosure are also directed to providing a display device in which an organic layer is formed integrally across all of sub-pixels, but, by forming a surface unevenness on a surface of a bank and at the same time, forming a trench, it is possible to minimize a lateral leakage current between adjacent sub-pixels.

Embodiments of the present disclosure are also directed to providing a display device in which, due to a process, after a bank is formed, a surface unevenness is formed on a bank during a coating and cleaning process of a photoresist that is performed while a mother panel moves, thereby improving complexity of a process.

Objects of the present disclosure are not limited to the above-described objects, and other technical objects can be inferred from the following embodiments.

According to one embodiment of the present disclosure, there is provided a display device including a substrate including a display area including a plurality of sub-pixels including a first sub-pixel, a second sub-pixel, and a third sub-pixel, and a non-display area around the display area, an anode electrode disposed in each of the sub-pixels on the substrate in the display area, a bank disposed on the anode electrode of the display area, located at a boundary between adjacent sub-pixels, and overlapping a periphery of an upper surface of the anode electrode, an organic layer disposed on the anode electrode and the bank in the display area and disposed across the plurality of sub-pixels, and a dam on the substrate in the non-display area, wherein the dam includes the bank, and a surface unevenness is formed on an upper surface of the bank in the display area.

Detailed matters of other embodiments of the present disclosure are included in the detailed description and accompanying drawings.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is a plan view of a display device according to one embodiment.

FIG. 2 is a cross-sectional view illustrating a bent state of a display panel according to FIG. 1.

FIG. 3 is a cross-sectional view along line A-A′ in FIG. 1.

FIG. 4 is a specific cross-sectional view of a light-emitting part of FIG. 3.

FIG. 5 is a specific cross-sectional view of a light-emitting part according to a modified example.

FIG. 6 is a cross-sectional view of a touch part according to FIG. 3.

FIG. 7 is a cross-sectional view along line B-B′ in FIG. 1.

FIG. 8 is a cross-sectional view along line C-C′ in FIG. 1.

FIG. 9 is a cross-sectional view along line D-D′ in FIG. 1.

FIG. 10A is an enlarged cross-sectional view of area Q1 in FIG. 3.

FIG. 10B is a cross-sectional view of a display panel according to a modified example.

FIGS. 11 to 15 are cross-sectional views for each process of a method of manufacturing a display device according to one embodiment of the present disclosure.

FIG. 16 is a cross-sectional view of a display device according to another embodiment of the present disclosure.

FIG. 17 is a cross-sectional view of a display device according to still another embodiment of the present disclosure.

FIG. 18 is a cross-sectional view of a display device according to yet another embodiment of the present disclosure.

FIG. 19 is a cross-sectional view of a display device according to yet another embodiment of the present disclosure.

FIG. 20 is a cross-sectional view of a display device according to yet another embodiment of the present disclosure.

FIG. 21 is a cross-sectional view of the display device according to yet another embodiment of the present disclosure.

FIG. 22 is a cross-sectional view of the display device according to yet another embodiment of the present disclosure.

FIG. 23 is a cross-sectional view of a display device according to yet another embodiment of the present disclosure.

FIG. 24 is a cross-sectional view of the display device according to yet another embodiment of the present disclosure.

FIG. 25 is a cross-sectional view of the display device according to yet another embodiment of the present disclosure.

FIG. 26 is a cross-sectional view of a display device according to yet another embodiment of the present disclosure.

### DETAILED DESCRIPTION OF THE EMBODIMENTS

Hereinafter, embodiments will be described with reference to the accompanying drawings.

The same reference numerals indicate the same components. In addition, in the drawings, thicknesses, proportions, and dimensions of components can be exaggerated for effective description of technical contents. Scales of components shown in the drawings differ from the actual scale for convenience of description, and thus are not limited to the scales shown in the drawings.

In the disclosure, when a first component (or an area, a layer, a portion, or the like) is described as “on,” “connected,” or “coupled to” a second component, it means that the first component can be directly connected/coupled to the second component or a third component can be disposed therebetween.

The term “and/or” includes all one or more combinations that can be defined by the associated configurations.

Terms such as first and second can be used to describe various components, but the components are not limited by the terms. The terms are used only for the purpose of distinguishing one component from another. For example, a first component can be referred to as a second component, and similarly, the second component can also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings. For example, as long as “immediately” or “directly” is not used, one or more other portions can be positioned between two portions. The spatially relative terms “below or beneath,” “lower,” “above,” “upper,” and the like can be used to easily describe the correlation with one element or components and another element or components as shown in the drawings. The spatially relative terms should be understood as the terms including different directions of elements in use or operation in addition to the directions shown in the drawings. For example, in case of turning the element shown in the drawing upside down, an element described as being disposed “below” or “beneath” another element can be disposed “above” another element. Accordingly, the example term “below” can include both downward and upward directions.

It should be understood that term such as “includes” or “has” is intended to specify the presence of features, numbers, steps, operations, components, parts, or a combination thereof described in the disclosure and does not preclude the presence or addition possibility of one or more other features, numbers, steps, operations, components, parts, or combinations thereof in advance.

Features of various embodiments of the present disclosure can be coupled or combined partially or entirely, various technological interworking and driving are made possible, and the embodiments can be implemented independently of each other or implemented together in an associated relationship.

Hereinafter, a display device of the present disclosure will be described with reference to the accompanying drawings and embodiments of the present disclosure as follows.

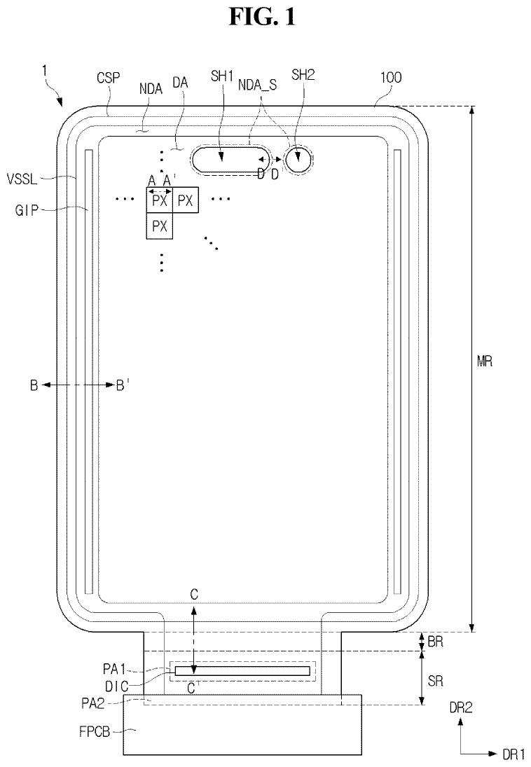

FIG. 1 is a plan view of a display device according to one embodiment of the present disclosure. All components of each display device according to all embodiments of the present disclosure are operatively coupled and configured.

Referring to FIG. 1, a display device 1 according to one embodiment can include a display panel 100. The display panel 100 can include a display area DA including a plurality of pixels PX and a non-display area NDA around the display area DA. The flat surface shape of the display area DA can have a rectangular shape. However, the embodiments of the present disclosure are not limited thereto, and the flat surface shape of the display area DA can be a square, circular, elliptical, or other polygonal shapes. For example, the display area DA can have a rectangular shape with rounded corners, but is not limited thereto and can also have a rectangular shape with angled corners.

In embodiments of the present disclosure, a first direction DR1 and a second direction DR2 are different directions and intersect each other, for example, directions that intersect vertically in a plan view. In FIG. 1, the first direction DR1 can be generally the same as an extension direction of short sides of the display panel 100, and the second direction DR2 can be the same as an extension direction of long sides of the display panel 100. However, the directions described in the embodiments of the present disclosure should be understood as indicating relative directions, and the embodiments of the present disclosure are not limited to the described directions.

The display area DA can include short sides extending in the first direction DR1 and long sides extending in the second direction DR2. The non-display area NDA can surround the display area DA. The non-display area NDA can be disposed at one side and the other side of the display area DA in the first direction DR1 and one side and the other side of the display area DA in the second direction DR2.

The display panel 100 can further include a sensor non-display area NDA_S and a sensor hole SH surrounded by the sensor non-display area NDA_S. The sensor hole SH1 and SH2 can be surrounded by the display area DA in a plan view. The sensor hole SH1 and SH2 can be, for example, two sensor holes as in FIG. 1, but the embodiments of the present disclosure are not limited thereto. For example, the sensor hole can be provided as one sensor hole. The two sensor holes SH1 and SH2 can each include a sensor hole in which an infrared sensor is disposed and a sensor hole in which a camera sensor is disposed, but the embodiments of the present disclosure are not limited thereto. The sensor non-display area NDA_S can be disposed between the sensor holes SH1 and SH2 and the display area DA. The sensor non-display area NDA_S can completely surround the sensor holes SH1 and SH2. A pixel PX can be not disposed in the sensor non-display area NDA_S.

A gate driving unit GIP can be disposed in the non-display area NDA located at one side and the other side of the display area DA in the first direction DR1. A low-potential voltage line VSSL can be disposed outside the gate driving unit GIP in the non-display area NDA. For example, as illustrated in FIG. 1, the low-potential voltage line VSSL can extend from a printed circuit board FPCB, pass a sub-region SR and a bending region BR, can be located outside the gate driving unit GIP in the non-display area NDA, and disposed to surround the display area DA.

The non-display area NDA located at the other side of the display area DA in the second direction DR2 can extend further from a central portion of the other side toward the other side of the display area DA in the second direction DR2. A width of the non-display area NDA in the first direction DR1 further extending from the central portion of the other side toward the other side of the display area DA in the second direction DR2 can be smaller than a width of the non-display area NDA in the first direction DR1 adjacent to the other side of the display area DA in the second direction DR2.

A display device 1 can include a main region MR, the sub-region SR, and the bending region BR between the main region MR and the sub-region SR. The display area DA and the non-display area NDA surrounding four surfaces of the display area DA can form the main region MR, and a portion extending from the central portion of the other side toward the other side of the display area DA in the second direction DR2 can form the bending region BR and the sub-region SR. The bending region BR can be disposed between the sub-region SR and the main region MR. The sub-region SR can include a first pad area PA1 and a second pad area PA2 located at an end portion of the other side of the sub-region SR in the second direction DR2. The display device 1 can further include a data driving unit DIC and a printed circuit board FPCB. The data driving unit DIC can be disposed in the first pad area PA1, and the printed circuit board FPCB can be attached to the second pad area PA2. A plurality of pads connected to the data driver 300 and the printed circuit board 500 can be disposed in each of the first pad area PA1 and the second pad area PA2. A plurality of pads connected to the data driving unit DIC and the printed circuit board FPCB can be disposed in each of the first pad area PA1 and the second pad area PA2. The data driving unit DIC can be configured, for example, in the form of a driving chip (IC), but is not limited thereto. In one embodiment of the present disclosure, a case in which the data driving unit DIC is disposed by a chip on plastic method in which the data driving unit DIC is directly mounted on the display panel 100 is described, but the embodiments of the present disclosure are not limited thereto, and the data driving unit DIC can be disposed by a chip on glass or chip on film method.

The display panel 100 according to one embodiment of the present disclosure can further include a crack sensing pattern CSP surrounding the low-potential voltage line VSSL. The crack sensing pattern CSP can be disposed to completely surround the display area DA as illustrated in FIG. 1. For example, the crack sensing pattern CSP can be disposed outside the low-potential voltage line VSSL. However, the embodiments of the present disclosure are not limited thereto, and a part of the crack sensing pattern CSP can be not disposed in the non-display area NDA of the other side of the display area DA in the second direction DR2.

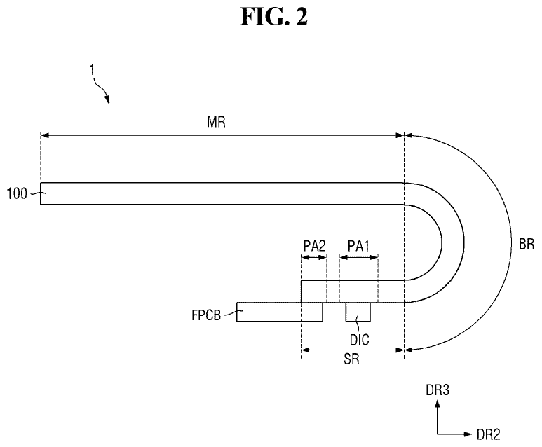

FIG. 2 is a cross-sectional view illustrating a bent state of a display panel according to FIG. 1.

Referring to FIG. 2, the bending region BR of the display panel 100 of the display device 1 according to one embodiment of the present disclosure can be bent in a thickness direction (or a third direction DR3). Accordingly, the main region MR and the sub-region SR can overlap each other in the thickness direction. The display panel 100 can be bent in such a manner that a lower surface of the main region MR faces an upper surface of the sub-region SR. The printed circuit board FPCB can be attached to an end portion of the sub-region SR.

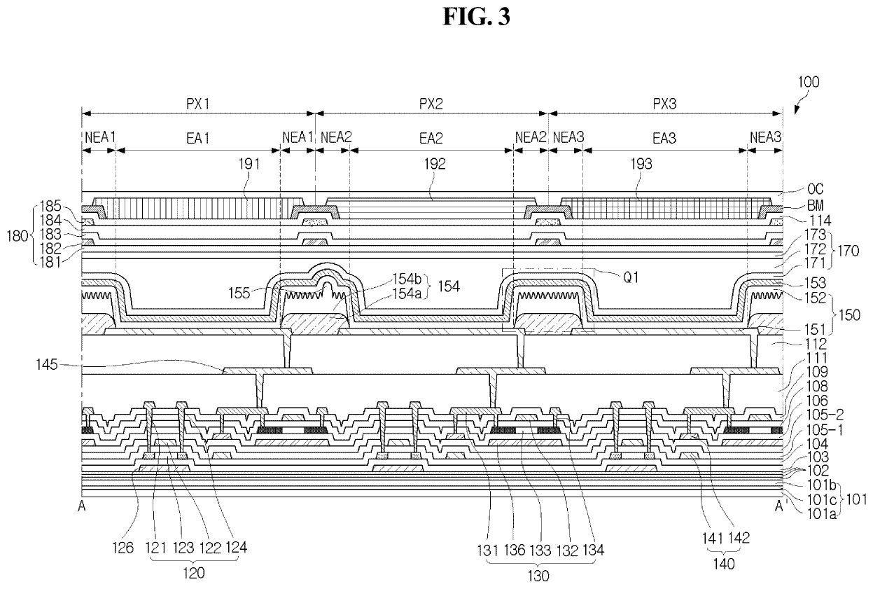

FIG. 3 is a cross-sectional view along line A-A′ in FIG. 1.

Referring to FIG. 3, the pixel PX (see FIG. 1) of the display panel 100 can include a plurality of sub-pixels PX1, PX2, and PX3. The first sub-pixel PX1 can be a red sub-pixel, the second sub-pixel PX2 can be a green sub-pixel, and the third sub pixel PX3 can be a blue sub-pixel, but the embodiments of the present disclosure are not limited thereto. In some embodiments, the pixel PX further includes a fourth sub-pixel, and the fourth sub-pixel can be a white sub-pixel, but the embodiments of the present disclosure are not limited thereto, and other colors can be used.

The display panel 100 can include a substrate 101, a first thin film transistor 120, a second thin film transistor 130, a light-emitting part 150, an encapsulation part 170, a touch part 180, a filter insulating layer 114, a black matrix BM, color filters 191, 192, and 193, and a planarization layer OC. The display panel 100 can include at least one panel insulating layer and at least one touch insulating layer between the substrate 101 and the light-emitting part 150. The at least one panel insulating layer can include at least one of a buffer layer 102, a first insulating layer 103, a second insulating layer 104, a 3-1 insulating layer 105-1, a 3-2 insulating layer 105-2, a fourth insulating layer 106, a fifth insulating layer 108, a sixth insulating layer 109, a first protective layer 111, and a second protective layer 112, and the at least one touch insulating layer can include at least one of a touch buffer layer 181, a first touch insulating layer 183, and a second touch insulating layer 184.

The substrate 101 can include one or more plastic materials. For example, the substrate 101 can be a multi-substrate including a plurality of plastic materials, such as polyimide, etc. For example, the substrate 101 can include a first substrate portion 101a and a second substrate portion 101b each including a plastic material, and a third substrate portion 101c including an inorganic insulation material between the first substrate portion 101a and the second substrate portion 101b, but the embodiments of the present disclosure are not limited thereto.

The buffer layer 102 can be disposed on the substrate 101. The buffer layer 102 can minimize or delay the diffusion of moisture or oxygen penetrating the substrate 101. The buffer layer 102 can be formed by alternately stacking silicon nitride (SiNx) and silicon oxide (SiOx) at least once, but the embodiments of the present disclosure are not limited thereto.

A first light-shielding layer 126 can be disposed on the buffer layer 102. The first light-shielding layer 126 can prevent light from reaching a first semiconductor layer 123 of the first thin film transistor 120. For example, the first semiconductor layer 123 can be disposed to overlap the first light-shielding layer 126. The first light-shielding layer 126 can be formed of a single layer or multiple layers formed of one of molybdenum (Mo), aluminum (Al), chromium (Cr), nickel (Ni), neodymium (Nd), and copper (Cu) or an alloy thereof, but the embodiments of the present disclosure are not limited thereto and other materials can be used.

The first insulating layer 103 can be disposed on the buffer layer 102 and the first light-shielding layer 126. The first insulating layer 103 can prevent a short circuit between a component of the first thin film transistor 120 and the first light-shielding layer 126. The first insulating layer 103 can be formed of the same material as the buffer layer 102, but the embodiments of the present disclosure are not limited thereto. For example, the first insulating layer 103 can be formed of an inorganic insulation material, such as silicon nitride (SiNx) or silicon oxide (SiOx), but the embodiments of the present disclosure are not limited thereto.

The first thin film transistor 120 can be disposed on the first insulating layer 103. The first thin film transistor 120 can include a first source electrode 121, a first gate electrode 122, the first semiconductor layer 123, and a first drain electrode 124.

The first semiconductor layer 123 can be disposed on the first insulating layer 103. The first semiconductor layer 123 can include a metal oxide semiconductor, such as indium-gallium-zinc oxide (IGZO), and a silicon-based semiconductor material, such as amorphous silicon, polycrystalline silicon, etc., but the embodiments of the present disclosure are not limited thereto. The first semiconductor layer 123 can include a channel area, a source area, and a drain area.

Since the polycrystalline semiconductor layer has higher mobility than the amorphous semiconductor layer and the oxide semiconductor layer, power consumption can be less, and reliability can be excellent. Accordingly, a driving transistor can be formed of the polycrystalline semiconductor layer.

A second insulating layer 104 can be disposed on the first semiconductor layer 123. The second insulating layer 104 can be formed of the same material as the first insulating layer 103 and can prevent a short circuit between the first semiconductor layer 123 and another component of the first thin film transistor 120.

The first gate electrode 122 can be disposed on the second insulating layer 104. The first gate electrode 122 can be disposed on the second insulating layer 104 to overlap the channel area of the first semiconductor layer 123. The first gate electrode 122 can be formed of a single layer or multiple layers formed of molybdenum (Mo), copper (Cu), titanium (Ti), aluminum (Al), chromium (Cr), gold (Au), nickel (Ni), neodymium (Nd), or compounds thereof, but the embodiments of the present disclosure are not limited thereto. The first gate electrode 122 can be disposed along with a gate line.

The third insulating layers 105-1 and 105-2 can be disposed on the first gate electrode 122. The third insulating layers 105-1 and 105-2 can be formed by alternately stacking silicon nitride (SiNx) and silicon oxide (SiOx) at least once, but the embodiments of the present disclosure are not limited thereto. For example, the 3-1 insulating layer 105-1 can include silicon oxide (SiOx), and the 3-2 insulating layer 105-2 can include silicon nitride (SiNx), but the embodiments of the present disclosure are not limited thereto, as other materials can be used, and additional layers can be present.

The first source electrode 121 and the first drain electrode 124 can be disposed on the third insulating layers 105-1 and 105-2.

The first source electrode 121 and the first drain electrode 124 can be electrically connected to the first semiconductor layer 123 through contact holes. The first source electrode 121 and the first drain electrode 124 can be formed of a metallic material. For example, the first source electrode 121 and the first drain electrode 124 can be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto, and other materials can be used.

The first source electrode 121 and the first drain electrode 124 can be disposed along with a data line. For example, the data line can be formed of the same material as the first source electrode 121 and the first drain electrode 124 and formed on the same layer as the first source electrode 121 and the first drain electrode 124, but the embodiments of the present disclosure are not limited thereto.

A storage electrode 140 can be disposed to be spaced apart from the first thin film transistor 120. The storage electrode 140 can include a first storage electrode 141 and a second storage electrode 142.

The first storage electrode 141 can be formed of the same material as the first gate electrode 122 and disposed on the same layer as the first gate electrode 122, but the embodiments of the present disclosure are not limited thereto.

The second storage electrode 142 can be disposed on the first storage electrode 141. The second storage electrode 142 can be disposed on the third insulating layers 105-1 and 105-2, and the third insulating layers 105-1 and 105-2 between the first storage electrode 141 and the second storage electrode 142 can be used as a dielectric to generate a capacitance. The second storage electrode 142 can be formed of the same material as the first storage electrode 141, but the embodiments of the present disclosure are not limited thereto.

The second thin film transistor 130 can be disposed to be spaced apart from the first thin film transistor 120 and the storage electrode 140. The second thin film transistor 130 can include a second source electrode 131, a second gate electrode 132, a second semiconductor layer 133, and a second drain electrode 134.

A second light-shielding layer 136 can be disposed on the same layer as the second storage electrode 142.

The second light-shielding layer 136 can prevent light from traveling to the second semiconductor layer 133 similar to the first light-shielding layer 126, thereby extending the life of the second thin film transistor 130. For example, the second semiconductor layer 133 can be disposed to overlap the second light-shielding layer 136.

The fourth insulating layer 106 can be disposed on the second light-shielding layer 136. The fourth insulating layer 106 can be formed of the same material as the first insulating layer 103, the second insulating layer 104, or the third insulating layers 105-1 and 105-2, but the embodiments of the present disclosure are not limited thereto.

The second semiconductor layer 133 can be disposed on the fourth insulating layer 106. The second semiconductor layer 133 can include a source area, a drain area, and a channel area between the source area and the drain area.

The second semiconductor layer 133 can include a metal oxide semiconductor, such as indium-gallium-zinc oxide (IGZO), and a silicon-based semiconductor material, such as amorphous silicon, polycrystalline silicon, etc., but the embodiments of the present disclosure are not limited thereto.

The fifth insulating layer 108 can be disposed on the second semiconductor layer 133. The fifth insulating layer 108 can be formed of the same material as the first insulating layer 103, the second insulating layer 104, the third insulating layers 105-1 and 105-2, or the fourth insulating layer 106, but the embodiments of the present disclosure are not limited thereto.

The second gate electrode 132 can be disposed on the fifth insulating layer 108.

The second gate electrode 132 can be formed of the same material as the first gate electrode 122. For example, the second gate electrode 132 can be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto as other materials can be used.

The sixth insulating layer 109 can be disposed on the second gate electrode 132. The sixth insulating layer 109 can be formed of the same material as the first insulating layer 103, the second insulating layer 104, the third insulating layers 105-1 and 105-2, the fourth insulating layer 106, or the fifth insulating layer 108, but the embodiments of the present disclosure are not limited thereto.

The first source electrode 121, the first drain electrode 124, the second source electrode 131, and the second drain electrode 134 can be disposed on the sixth insulating layer 109.

The second source electrode 131 and the second drain electrode 134 can be formed of the same material as the first source electrode 121 and the first drain electrode 124 and disposed on the same layer as the first source electrode 121 and the first drain electrode 124, but the embodiments of the present disclosure are not limited thereto. For example, the second source electrode 131 and the second drain electrode 134 can be formed of a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto as other materials can be used. For example, the second source electrode 131 can be electrically connected to the second storage electrode 142. The second source electrode 131 can pass through the sixth insulating layer 109, the fifth insulating layer 108, and the fourth insulating layer 106 and can be electrically connected to the second storage electrode 142.

The first thin film transistor 120 can be a driving transistor, and the second thin film transistor 130 can be a switching transistor, but the embodiments of the present disclosure are not limited thereto.

A first protective layer 111 can be disposed on the first source electrode 121 and the first drain electrode 124.

The first protective layer 111 can planarize an upper portion of the first thin film transistor 120 and protect the first thin film transistor 120. The first protective layer 111 can be formed of an organic material. For example, the first protective layer 111 can be formed of an organic material containing an acrylic resin, an epoxy resin, a phenolic resin, a polyamide resin, or a polyimide resin, but the embodiments of the present disclosure are not limited thereto, and other materials can be used.

The second protective layer 112 can be disposed on the first protective layer 111. The second protective layer 112 can be formed of the same material as the first protective layer 111, but the embodiments of the present disclosure are not limited thereto.

In some embodiments, a third protective layer can be further disposed on an upper surface of the second protective layer 112, but the embodiments of the present disclosure are not limited thereto.

A connection electrode 145 can be disposed between the first protective layer 111 and the second protective layer 112.

The connection electrode 145 can electrically connect the first thin film transistor 120 to the light-emitting part 150. The connection electrode 145 can be formed of the same material as the first source electrode 121 and the first drain electrode 124, but the embodiments of the present disclosure are not limited thereto.

The connection electrode 145 can be formed of a single layer or multiple layers made of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto, and other materials can be used.

The light-emitting part 150 can be disposed on the second protective layer 112. The light-emitting part 150 can include an anode electrode 151, an organic layer 152, and a cathode electrode 153.

The anode electrode 151 can be disposed on the second protective layer 112. The anode electrode 151 can be electrically connected to the first thin film transistor 120 through a contact hole formed in the second protective layer 112. The anode electrode 151 can be a reflective electrode that reflects light, but the embodiments of the present disclosure are not limited thereto. The anode electrode 151 can include a metallic material with high reflectivity, such as a stacking structure (Ti/Al/Ti) of aluminum (Al) and titanium (Ti), a stacking structure (ITO/Al/ITO) of aluminum (Al) and indium tin oxide (ITO), or an APC alloy and can be formed of a single layer or multiple layers, but the embodiments of the present disclosure are not limited thereto.

The organic layer 152 can be disposed on the anode electrode 151. The organic layer 152 can include one or more light-emitting structures (or light-emitting elements or elements) stacked on the anode electrode 151 in the order or reverse order of a hole transfer layer and an electron transfer layer. For example, the hole transfer layer can include a hole transporting layer, a hole injecting layer, an electron blocking layer, a p-type charge generation layer, etc., but the embodiments of the present disclosure are not limited thereto. For example, the electron transfer layer can include an electron transporting layer, an electron injecting layer, a hole blocking layer, an n-type charge generation layer, etc., but the embodiments of the present disclosure are not limited thereto. The organic layer 152 can be an organic light-emitting layer, an inorganic light-emitting layer, a quantum dot light-emitting layer, a micro light-emitting diode, a micro mini light-emitting diode, etc., but the embodiments of the present disclosure area not limited thereto. For example, the organic layer 152 of the display panel 100 according to one embodiment of the present disclosure can include an organic light-emitting layer. The organic layer 152 can include a red light-emitting layer, a green light-emitting layer, and a blue light-emitting layer. The organic layer 152 can be a white light-emitting layer, but the embodiments of the present disclosure are not limited thereto. Hereinafter, a specific structure of the organic layer 152 according to one embodiment will be described.

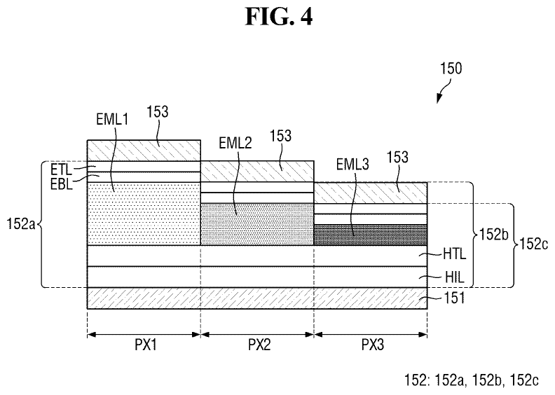

FIG. 4 is a specific cross-sectional view of a light-emitting part of FIG. 3.

Referring to FIG. 4, the light-emitting part 150 can include the first sub-pixel PX1, the second sub-pixel PX2, and the third sub-pixel PX3.

A thickness of the light-emitting part 150 in each sub-pixel PX1, PX2, or PX3 can be different, but the embodiments of the present disclosure are not limited thereto, and the thickness of the light-emitting part 150 in each sub-pixel PX1, PX2, or PX3 can be the same.

The organic layer 152 can include a first organic layer 152a disposed in the first sub-pixel PX1, a second organic layer 152b disposed in the second sub-pixel PX2, and a third organic layer 152c disposed in the third sub-pixel PX3. The light-emitting layers EML1, EML2, and EML3 of the organic layers 152a, 152b, and 152c can be physically separated, but lower layers and upper layers of the light-emitting layers EML1, EML2, and EML3 can be formed integrally across the sub-pixels PX1, PX2, and PX3. A thicknesses of each light-emitting layer EML1, EML2, or EML3 can be different. For example, a thickness of a first light-emitting layer EML1 can be the greatest, a thickness of a second light-emitting layer EML2 can be the second greatest, and a thickness of the third light-emitting layer EML3 can be the smallest, but the embodiments of the present disclosure are not limited thereto.

The hole injecting layer HIL can be disposed on the anode electrode 151. The hole injecting layer HIL can be located between the anode electrode 151 and the light-emitting layers EML1, EML2, and EML3. The hole injecting layer HIL can be formed integrally across the sub-pixels PX1, PX2, and PX3. For example, the hole injecting layer HIL can be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present disclosure are not limited thereto.

A hole transporting layer HTL can be disposed on the hole injecting layer HIL. The hole transporting layer HTL can be located between the hole injecting layer HIL and the light-emitting layers EML1, EML2, and EML3. The hole transporting layer HTL can be formed integrally across the sub-pixels PX1, PX2, and PX3. The hole transporting layer HTL can be formed of one or more selected from the group consisting of arylamine-based materials, such as NPB (N,N-naphthyl-N,N′-phenyl benzidine), TPD (N,N′-bis-(3-methylphenyl)-N, N′-bis-(phenyl)-benzidine), PPD, TTBND, FFD, p-dmDPS, and TAPC, starburst aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthyIN, N′-diphenyl benzidine), s-TAD, and MTDATA(4,4′,4″-Tris(N-3-methylphenyl-N-phenyl-amino)-triphenylamine), but the embodiments of the present disclosure are not limited thereto.

The light-emitting layers EML1, EML2, and EML3 can be disposed on the hole transporting layer HTL. The first light-emitting layer EML1 can be disposed in the first sub-pixel PX1, the second light-emitting layer EML2 can be disposed in the second sub-pixel PX2, and the third light-emitting layer EML3 can be disposed in the third sub-pixel PX3.

A thicknesses of each light-emitting layer EML1, EML2, or EML3 can be different. For example, the first light-emitting layer EML1 can be formed in a thickness of 600 to 800 Å, the second light-emitting layer EML2 can be formed in a thickness of 300 to 500 Å, and the third light-emitting layer EML3 can be formed in a thickness of 100 to 300 Å, but the embodiments of the present disclosure are not limited thereto.

Each of the first light-emitting layer EML1, the second light-emitting layer EML2, and the third light-emitting layer EML3 can include a material that can emit light in the visible light range by receiving and combining holes and electrons.

An electron blocking layer EBL can be disposed on each light-emitting layer EML1, EML2, or EML3. The electron blocking layer EBL can be disposed integrally across the sub-pixels PX1, PX2, and PX3.

An electron transporting layer ETL can be disposed on the electron blocking layer EBL. The electron transporting layer ETL can be disposed integrally across the sub-pixels PX1, PX2, and PX3. The electron transporting layer ETL can be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present disclosure are not limited thereto.

The cathode electrode 153 can be disposed on the electron transporting layer ETL.

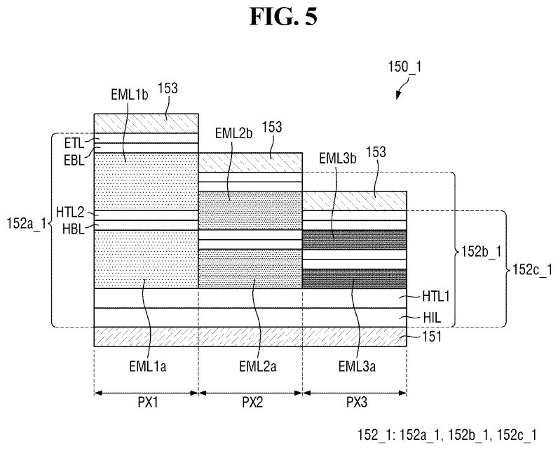

FIG. 5 is a specific cross-sectional view of a light-emitting part according to a modified example.

Referring to FIGS. 4 and 5, an organic layer 152_1 can include a first organic layer 152a_1 disposed in the first sub-pixel PX1, a second organic layer 152b_1 disposed in the second sub-pixel PX2, and a third organic layer 152c_1 disposed in the third sub-pixel PX3.

The light-emitting layers of each organic layer 152a_1, 152b_1, or 152c_1 can be physically separated, but the lower layers and upper layers of the light-emitting layers can be formed integrally across the sub-pixels PX1, PX2, and PX3. The thickness of each light-emitting layer can be different. For example, the thickness of the first light-emitting layer of the first sub-pixel can be the greatest, the thickness of the second light-emitting layer of the second sub-pixel can be the second greatest, and the thickness of the third light-emitting layer of the third sub-pixel can be the smallest, but the embodiments of the present disclosure are not limited thereto. In addition, the light-emitting layers of each organic layer 152a_1, 152b_1, or 152c_1 can be provided as two or more light-emitting layers.

The hole injecting layer HIL can be disposed on the anode electrode 151. The hole injecting layer HIL can be located between the anode electrode 151 and the light-emitting layers EML1a, EML2a, and EML3a. The hole injecting layer HIL can be formed integrally across the sub-pixels PX1, PX2, and PX3. For example, the hole injecting layer HIL can be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present disclosure are not limited thereto.

A first hole transporting layer HTL1 can be disposed on the hole injecting layer HIL. The first hole transporting layer HTL1 can be located between the hole injecting layer HIL and light-emitting layers EML1a, EML2a, and EML3a. The first hole transporting layer HTL1 can be formed integrally across the sub-pixels PX1, PX2, and PX3. The first hole transporting layer HTL1 can be formed of one or more selected from the group consisting of arylamine-based materials, such as NPB (N, N-naphthyl-N,N′-phenyl benzidine), TPD (N,N′-bis-(3-methylphenyl)-N, N′-bis-(phenyl)-benzidine), PPD, TTBND, FFD, p-dmDPS, and TAPC, starburst aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N, N-dinaphthyIN, N′-diphenyl benzidine), s-TAD, and MTDATA(4,4′,4″-Tris(N-3-methylphenyl-N-phenyl-amino)-triphenylamine), but the embodiments of the present disclosure are not limited thereto.

The light-emitting layers EML1a, EML2a, and EML3a can be disposed on the first hole transporting layer HTL1. A 1-1 light-emitting layer EML la can be disposed in the first sub-pixel PX1, a 2-1 light-emitting layer EML2a can be disposed in the second sub-pixel PX2, and a 3-1 light-emitting layer EML3a can be disposed in the third sub-pixel PX3. Each of the light-emitting layers EML1a, EML2a, and EML3a can be the same as each of the light-emitting layers EML1, EML2, and EML3 of FIG. 4.

A thicknesses of each light-emitting layer EML1a, EML2a, or EML3a can be different. For example, the 1-1 light-emitting layer EML la can be formed in a thickness of 600 to 800 Å, the 2-1 light-emitting layer EML2a can be formed in a thickness of 300 to 500 Å, and the 3-1 light-emitting layer EML3a can be formed in a thickness of 100 to 300 Å, but the embodiments of the present disclosure are not limited thereto.

A hole blocking layer HBL can be disposed on each light-emitting layer EML1a, EML2a, or EML3a. The hole blocking layer HBL can be disposed integrally across the sub-pixels PX1, PX2, and PX3.

A second hole transporting layer HTL2 can be disposed on the hole blocking layer HBL. The second hole transporting layer HTL2 can be disposed between the hole blocking layer HBL and the light-emitting layers EML1b, EML2b, and EML3b. The second hole transporting layer HTL2 can be formed integrally across the sub-pixels PX1, PX2, and PX3. A material of the second hole transporting layer HTL2 can be the same as a material of the first hole transporting layer HTL1, but the embodiments of the present disclosure are not limited thereto.

The light-emitting layers EML1b, EML2b, and EML3b can be disposed on the second hole transporting layer HTL2. A 1-2 light-emitting layer EML1b can be disposed in the first sub-pixel PX1, a 2-2 light-emitting layer EML2b can be disposed in the second sub-pixel PX2, and a 3-2 light-emitting layer EML3b can be disposed in the third sub-pixel PX3. Each of the light-emitting layers EML1b, EML2b, and EML3b can be the same as each of the light-emitting layers EML1a, EML2a, and EML3a.

A thicknesses of each light-emitting layer EML1b, EML2b, or EML3b can be different. For example, the 1-2 light-emitting layer EML1b can be formed in a thickness of 600 to 800 Å, the 2-2 light-emitting layer EML2b can be formed in a thickness of 300 to 500 Å, and the 3-2 light-emitting layer EML3b can be formed in a thickness of 100 to 300 Å, but the embodiments of the present disclosure are not limited thereto.

An electron blocking layer EBL can be disposed on each light-emitting layer EML1b, EML2b, or EML3b. The electron blocking layer EBL can be disposed integrally across the sub-pixels PX1, PX2, and PX3.

An electron transporting layer ETL can be disposed on the electron blocking layer EBL. The electron transporting layer ETL can be disposed integrally across the sub-pixels PX1, PX2, and PX3. The electron transporting layer ETL can be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthaleny1-2-anthraceny1)phenyl]-1-phenyl-1H-benzimidazole), but the embodiments of the present disclosure are not limited thereto.

The cathode electrode 153 can be disposed on the electron transporting layer ETL. The cathode electrode 153 can be a transparent electrode that transmits light, but the embodiments of the present disclosure are not limited thereto. For example, the cathode electrode 153 can include a transparent conductive material, such as indium tin oxide (ITO) or indium zinc oxide (IZO), or a metal that transmits visible light, but the embodiments of the present disclosure are not limited thereto, and other materials can be used.

A bank 154 can be disposed to expose the anode electrode 151. The bank 154 can define openings (or the light-emitting areas EA1, EA2, and EA3) of the sub-pixels PX1, PX2, and PX3 and can be disposed to cover an edge portion (or a periphery) of the anode electrode 151. For example, the first sub-pixel PX1 can include a first light-emitting area EA1 and a first non-light-emitting area NEA1 around the first light-emitting area EA1, the second sub-pixel PX2 can include a second light-emitting area EA2 and a second non-light-emitting area NEA2 around the second light-emitting area EA2, and the third sub-pixel PX3 can include a third light-emitting area EA3 and a third non-light-emitting area NEA3 around the third light-emitting area EA3. For example, each non-light-emitting area NEA1, NEA2, or NEA3 can correspond to a boundary between adjacent sub-pixels PX1, PX2, and PX3.

The bank 154 can include two or more layers. For example, the bank 154 can include a first bank 154a, and a second bank 154b between the first bank 154a and the organic layer 152. The first bank 154a can include a black-based material (or an opaque material). For example, the first bank 154a can be formed of a material containing black pigment, or an organic material, such as a benzocyclobutene resin, a polyimide resin, an acrylic resin, a photosensitive polymer, etc., but the embodiments of the present disclosure are not limited thereto. When the first bank 154a is formed of a material containing black pigment or black dye, the first bank 154a can be a black bank. When the first bank 154a is formed of a material containing black pigment or black dye, it is possible to shield external light or light reflected from the outside, thereby further increasing the luminance of the display device. The first bank 154a can serve to absorb light re-reflected from a lower portion of the first bank 154a among the light incident from the outside. The second bank 154b can include a transparent-based material. The second bank 154b can be a transparent bank, but the embodiments of the present disclosure are not limited thereto.

FIG. 3 illustrates a width of the first bank 154a, which is the same as a width of the second bank 154b, but the embodiments of the present disclosure are not limited thereto. In some embodiments, the width of the first bank 154a can be greater than the width of the second bank 154b, and an end of the second bank 154b can be located farther from boundaries between the light-emitting areas EA1, EA2, and EA3 and the non-light-emitting areas NEA1, NEA2, and NEA3 than an end of the first bank 154a. For example, the second bank 154b can expose a part of an upper surface of the first bank 154a. In some other embodiments, the width of the first bank 154a can be smaller than the width of the second bank 154b, and the second bank 154b can completely cover the side surfaces of the first bank 154a.

A surface unevenness (or surface irregularities) can be formed on an upper surface of the second bank 154b. The detailed descriptions thereof will be given below. In various embodiments of the present disclosure, reference to an unevenness or an irregularity of a surface, such as a surface unevenness or a surface irregularity, can be for a structure or topographical feature of a surface being not smooth. For example, a surface having unevenness or irregularities can have peaks and/or valleys that extend over the surface. Heights of the peaks and depths of the valleys can be constant or can vary. For example, the heights of the peaks can be the same or different from each other, and depths of the valleys can be the same or different from each other. In other embodiments of the present disclosure, the heights of the peaks can be the same or different from the depths of the valleys. Further, sizes of the peaks and/or valleys can be constant or vary. In various embodiments of the present disclosure, one or more peaks and one or more valleys can have flat, level or plateau portions, but embodiments of the present disclosure are not limited thereto.

A spacer 155 can be further disposed on the bank 154. The spacer 155 can be formed of the same material as the second bank 154b, but the embodiments of the present disclosure are not limited thereto, and different materials can be used for the spacer 155 and the bank 155. For example, the spacer 155 can be a different layer from the bank 154, such as the second bank 154b. For example, the spacer 155 can be a transparent bank. For example, the spacer 155 can be disposed on at least one of the boundaries of the first to third sub-pixels PX1, PX2, and PX3, but the embodiments of the present disclosure are not limited thereto. In some embodiments, the second bank 154b and the spacer 155 can be formed of the same material and formed simultaneously through a halftone mask, but the embodiments of the present disclosure are not limited thereto. The surface unevenness can be not formed on a surface of the spacer 155. For example, the roughness of the surface of the spacer 155 can be smaller than the roughness of the surface of the second bank 154b.

The organic layer 152 can be disposed on the anode electrode 151, the bank 154, and the spacer 155. The cathode electrode 153 can be disposed on the organic layer 152.

The encapsulation part 170 can be disposed on the cathode electrode 153. The encapsulation part 170 can include one or more insulating layers. For example, the encapsulation part 170 can include a first encapsulation layer 171, a second encapsulation layer 172 disposed on the first encapsulation layer 171, and a third encapsulation layer 173 disposed on the second encapsulation layer 172. The encapsulation part 170 can include one or more inorganic insulation material layers and one or more organic material layers. For example, the first encapsulation layer 171 and the third encapsulation layer 173 can include an inorganic insulation material, and the second encapsulation layer 172 can include an organic material, but the embodiments of the present disclosure are not limited thereto.

The touch part 180 can be disposed on the encapsulation part 170. The touch part 180 can include the touch buffer layer 181, a first touch conductive layer, the first touch insulating layer 183, the second touch insulating layer 184, and a second touch conductive layer. In some embodiments, a touch organic layer can be further disposed on the second touch conductive layer, but the embodiments of the present disclosure are not limited thereto.

Meanwhile, as illustrated in FIG. 3, a spacing distance between an end of the black matrix BM and a boundary between the first light-emitting area EA1 and the first non-light-emitting area NEA1 can be longer than a spacing distance between an end of the bank 154 and the boundary between the first light-emitting area EA1 and the first non-light-emitting area NEA1. The end of the bank 154 can be aligned with the boundary between the first light-emitting area EA1 and the first non-light-emitting area NEA1, but the embodiments of the present disclosure are not limited thereto. In the case of the display panel 100 according to one embodiment, the bank 154 (the first bank 154a) can include a black-based material, and since the spacing distance between the end of the black matrix BM and the boundary between the first light-emitting area EA1 and the first non-light-emitting area NEA1 can be longer than the spacing distance between the end of the bank 154 and the boundary between the first light-emitting area EA1 and the first non-light-emitting area NEA1, light emitted from the first light-emitting area EA1 can be emitted upward with a greater viewing angle as much as a spacing space between the end of the black matrix BM and the boundary between the first light-emitting area EA1 and the first non-light-emitting area NEA1. Accordingly, it is possible to minimize a reduction in luminance according to a viewing angle. However, when the spacing distance between the end of the black matrix BM and the boundary between the first light-emitting area EA1 and the first non-light-emitting area NEA1 is longer than the spacing distance between the end of the bank 154 and the boundary between the first light-emitting area EA1 and the first non-light-emitting area NEA1 and the bank 154 is formed of a transparent material, light incident from the outside can be reflected by the bank 154, resulting in visible ring-shaped spots. However, in the case of the display panel 100 according to one embodiment, the light incident from the outside can be absorbed or blocked by the bank 154 including a black-based material, thereby preventing the occurrence of the ring-shaped spots.

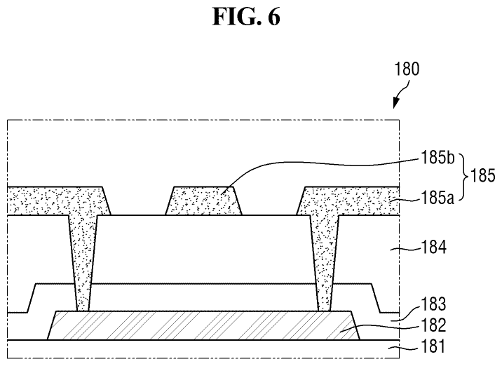

FIG. 6 is a cross-sectional view of a touch part according to FIG. 3.

Referring to FIGS. 3 and 6, the touch buffer layer 181 can be disposed on the encapsulation part 170. For example, the touch buffer layer 181 can be disposed on the third encapsulation layer 173. The touch buffer layer 181 can be formed of the same material as the buffer layer 102, but the embodiments of the present disclosure are not limited thereto.

The first touch conductive layer can be disposed on the touch buffer layer 181. The first touch conductive layer can include a bridge electrode 182. The bridge electrode 182 and a sensor electrode 185 to be described below can be disposed at each of the boundaries between adjacent sub-pixels PX1, PX2, and PX3. For example, the bridge electrode 182 and the sensor electrode 185 can be disposed in the non-light-emitting areas NEA1, NEA2, and NEA3. The bridge electrode 182 and the sensor electrode 185 can overlap the black matrix BM to be described below in the thickness direction. The black matrix BM can cover the bridge electrode 182 and the sensor electrode 185. Accordingly, the bridge electrode 182 and the sensor electrode 185 can be prevented from being visible from the outside.

The first touch insulating layer 183 and the second touch insulating layer 184 disposed on the first touch insulating layer 183 can be disposed on the first touch conductive layer. The first touch insulating layer 183 and the second touch insulating layer 184 disposed on the first touch insulating layer 183 can prevent a short circuit between the first touch conductive layer and the second touch conductive layer. The first touch insulating layer 183 can be formed of silicon oxide (SiOx), silicon nitride (SiNx), or multiple layers thereof, but the embodiments of the present disclosure are not limited thereto. The second touch insulating layer 184 can include an organic insulation material, but the embodiments of the present disclosure are not limited thereto, and the second touch insulating layer 184 can include the same material as the first touch insulating layer 183.

The second touch conductive layer can be disposed on the second touch insulating layer 184. The second touch conductive layer can include a first sensor electrode 185a and a second sensor electrode 185b. The sensor electrode 185 can include the first sensor electrode 185a extending in the first direction DR1 (see FIG. 1) and the second sensor electrode 185b extending in the second direction DR2 (see FIG. 1) different from the first direction DR1.

The bridge electrode 182 can be electrically connected to the first sensor electrode 185a through contact holes formed in the first touch insulating layer 183 and the second touch insulating layer 184. For example, the first sensor electrode 185a and the bridge electrode 182 can extend in the first direction DR1 (see FIG. 1).

The sensor electrode 185 and the bridge electrode 182 can include a metallic material. For example, the sensor electrode 185 and the bridge electrode 182 can be formed of titanium (Ti), nickel (Ni), aluminum (Al), or an alloy thereof and formed of a triple layer, such as titanium (Ti)/aluminum (Al)/titanium (Ti), but the embodiments of the present disclosure are not limited thereto, and other materials can be used.

A filter insulating layer 114 can be disposed on the second touch conductive layer. The filter insulating layer 114 can be formed of an inorganic insulation material, such as silicon nitride (SiNx) or silicon oxide (SiOx), but the embodiments of the present disclosure are not limited thereto, and other materials can be used.

The black matrix BM can be disposed on the filter insulating layer 114. The black matrix BM can include a black-based material. For example, the black matrix BM can include a light-blocking material or a light-absorbing material. For example, the black matrix BM can be formed of a material including a black pigment, a black dye, etc. The black matrix BM can cover the bridge electrode 182 and the sensor electrode 185. Accordingly, the bridge electrode 182 and the sensor electrode 185 can be prevented from being visible from the outside. For example, a width of the black matrix BM can be smaller than a width of the bank 154.

The color filters 191, 192, and 193 can be disposed on the black matrix BM.

The color filters 191, 192, and 193 can be disposed on the first to third sub-pixels PX1, PX2, and PX3, respectively, and can block specific colors from light emitted from the light-emitting area EA1, EA2, and EA3 of the sub-pixels PX1, PX2, and PX3. A first color filter 191 can be provided to block light of other colors not including red (R) light. In this case, the first color filter 191 can be provided as a red color filter. A second color filter 192 can be provided to block light of other colors not including green (G) light. In this case, the second color filter 192 can be provided as a green color filter. A third color filter 193 provided in the third sub-pixel PX3 can be provided to block light of other colors not including blue (B) light. In this case, the third color filter 193 can be provided as a blue color filter. However, the embodiments of the present disclosure are not limited thereto.

For example, each color filter 191, 192, or 193 can come into direct contact with side and upper surfaces of the black matrix BM. For example, each color filter 191, 192, or 193 can be spaced apart from the boundaries of adjacent sub-pixels PX1, PX2, and PX3, but the embodiments of the present disclosure are not limited thereto, and the color filters 191, 192, and 193 can overlap each other in the thickness direction.

The planarization layer OC can be disposed on the color filters 191, 192, and 193. The planarization layer OC can serve to planarize a step formed by the color filters 191, 192, and 193. For example, the planarization layer OC can include an organic insulation material.

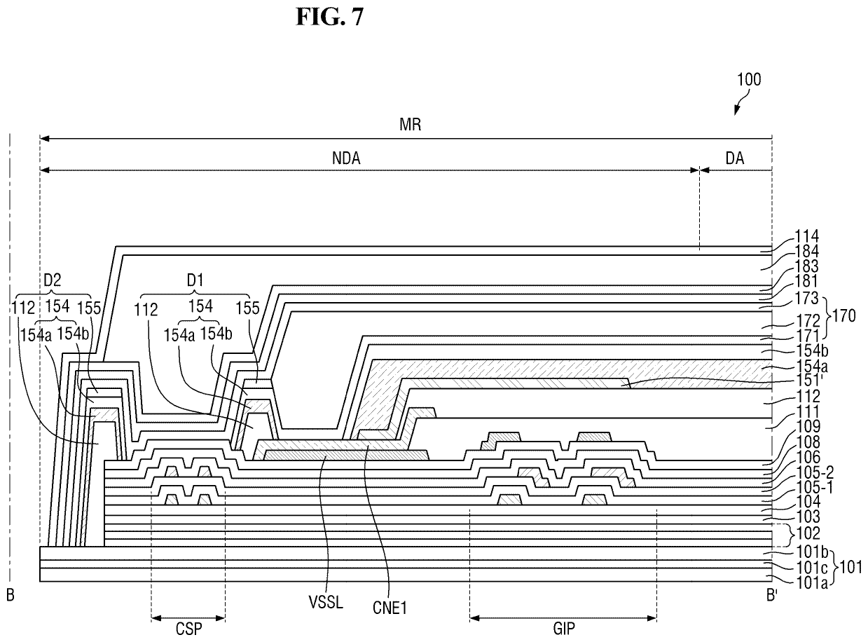

FIG. 7 is a cross-sectional view along line B-B′ in FIG. 1.

Referring to FIG. 7, at least one of the panel inorganic layers 102, 103, 104, 105-1, 105-2, 106, 108, and 109 can be not extended to the end portion of the substrate 101. For example, the at least one of the panel inorganic layers 102, 103, 104, 105-1, 105-2, 106, 108, and 109 can expose the end portion of the substrate 101, but the embodiments of the present disclosure are not limited thereto.

The display panel 100 according to one embodiment can further include the crack sensing pattern CSP, the low-potential voltage line VSSL, and the gate driving unit GIP. As described above in FIG. 1, the low-potential voltage line VSSL can be located between the crack sensing pattern CSP and the display area DA, and the gate driving unit GIP can be located between the low-potential voltage line VSSL and the display area DA.

For example, as illustrated in FIG. 7, the gate driving unit GIP can be formed of a conductive layer located on the same layer as the first gate electrode 122 (see FIG. 3), a conductive layer located on the same layer as the second light-shielding layer 136 (see FIG. 3), or a conductive layer located on the same layer as the first source electrode 121, but the embodiments of the present disclosure are not limited thereto.

For example, the crack sensing pattern CSP can be disposed between a first dam D1 and a second dam D2. The crack sensing pattern CSP can be formed of a conductive layer located on the same layer as the first gate electrode 122 (see FIG. 3) or a conductive layer located on the same layer as the second light-shielding layer 136 (see FIG. 3), but the embodiments of the present disclosure are not limited thereto. For example, the crack sensing pattern CSP can include a conductive layer located on the same layer as the first source electrode 121, but the embodiments of the present disclosure are not limited thereto.

The low-potential voltage line VSSL can be disposed between the crack sensing pattern CSP and the gate driving unit GIP. The low-potential voltage line VSSL can be formed of a conductive layer located on the same layer as the first source electrode 121, but the embodiments of the present disclosure are not limited thereto.

The first protective layer 111 can cover the gate driving unit GIP, partially cover one end portion of the low-potential voltage line VSSL, and expose the other end portion of the low-potential voltage line VSSL. In the present disclosure, the one end portion can refer to an area of a certain component, which is located in a direction from the non-display area NDA toward the display area DA, and the other end portion can refer to an area of the certain component, which is located in a direction from the display area DA toward the non-display area NDA.

A first connection electrode CNE1 located on the same layer as the connection electrode 145 can be disposed on the first protective layer 111. The first connection electrode CNE1 can be directly connected to an area of the low-potential voltage line VSSL, in which the first protective layer 111 is exposed. The first connection electrode CNE1 can cover the other end portion of the low-potential voltage line VSSL, but the embodiments of the present disclosure are not limited thereto.

The second protective layer 112 can be disposed on the first connection electrode CNE1. The second protective layer 112 can come into direct contact with and cover one end portion of the first connection electrode CNE1 and expose the other end portion of the first connecting electrode CNE1.

The second protective layer 112 can form a first layer of the first dam D1 and a first layer of the second dam D2. The second dam D2 can overlap, for example, the low-potential voltage line VSSL and cover the other end portion of the low-potential voltage line VSSL. The second dam D2 can come into direct contact with the first connection electrode CNE1 and cover the other end portion of the first connection electrode CNE1. The second protective layer 112 forming the first layer of the first dam D1 can come into direct contact with the exposed side surfaces of at least one of the panel inorganic layers 102, 103, 104, 105, 106, 107, and 109 and can come into direct contact with the upper surface of the substrate 101, but the embodiments of the present disclosure are not limited thereto. The second protective layer 112 can overlap the gate driving unit GIP. In the present disclosure, the dam is, for example, provided as two dams, but the dam can be provided as three or more dams or one dam.

A low-potential connection electrode 151′located on the same layer as the anode electrode 151 (see FIG. 3) can be disposed on the first connection electrode CNE1 exposed by the second protective layer 112 and the second protective layer 112. The low-potential connection electrode 151′can be electrically connected to the first connection electrode CNE1 exposed by the second protective layer 112. The low-potential connection electrode 151′can be electrically connected to the cathode electrode 153 (see FIG. 3) described above in FIG. 3.

The bank 154 can be disposed on the low-potential connection electrode 151′and the second protective layer 112. The bank 154 can overlap the gate driving unit GIP, overlap the low-potential connection electrode 151′, and cover the other end portion of the low-potential connection electrode 151′. The bank 154 can completely cover the low-potential connection electrode 151′, but the embodiments of the present disclosure are not limited thereto. The bank 154 can expose a central portion and the other end portion of the first connection electrode CNE1, but the embodiments of the present disclosure are not limited thereto. The first bank 154a of the bank 154 can form a second layer of the first dam D1 and a second layer of the second dam D2. In each dam D1 or D2, the first bank 154a can overlap the second protective layer 112 forming the first layer and completely cover the second protective layer 112, but the embodiments of the present disclosure are not limited thereto. In the second dam D2, the first bank 154a can come into contact with the side surfaces of the second protective layer 112 and the upper surface of the substrate 101, but the embodiments of the present disclosure are not limited thereto. The second bank 154b can form a third layer of the dam D1 or D2. The second bank 154b forming the third layer of each dam D1 or D2 can overlap the first bank 154a forming the second layer and completely cover the first bank 154a, but the embodiments of the present disclosure are not limited thereto. In the second dam D2, the second bank 154b can come into contact with the side surfaces of the first bank 154a and the upper surface of the substrate 101, but the embodiments of the present disclosure are not limited thereto.

The spacer 155 can form a fourth layer of the first dam D1 and a fourth layer of the second dam D2. In each dam D1 or D2, the spacer 155 can overlap the second bank 154b forming the third layer. In the second dam D2, the spacer 155 can overlap the second bank 154b forming the third layer.

The encapsulation part 170 can be disposed on the spacer 155. The first encapsulation layer 171 can extend to the gate driving unit GIP, the low-potential voltage line VSSL, the first dam D1, and the second dam D2 and cover an outer surface of the second dam D2. The second encapsulation layer 172 can end at the first dam D1. The second encapsulation layer 172 can overlap the gate driving unit GIP and the low-potential voltage line VSSL. The third encapsulation layer 173 can extend to the gate driving unit GIP, the low-potential voltage line VSSL, the first dam D1, and the second dam D2 and come into direct contact with the first encapsulation layer 171 on the first dam D1, the crack sensing pattern CSP, and the second dam D2.

The touch buffer layer 181 and the first touch insulating layer 183 can extend to the gate driving unit GIP, the low-potential voltage line VSSL, the first dam D1, and the second dam D2 and cover the outer surface of the second dam D2. The second touch insulating layer 184 can extend to the gate driving unit GIP, the low-potential voltage line VSSL, the first dam D1, and the crack sensing pattern CSP and end on the second dam D2, but the embodiments of the present disclosure are not limited thereto.

The filter insulating layer 184 can extend to the gate driving unit GIP, the low-potential voltage line VSSL, the first dam D1, and the second dam D2 and come into direct contact with an outer surface of the second touch insulating layer 184, but the embodiments of the present disclosure are not limited thereto.

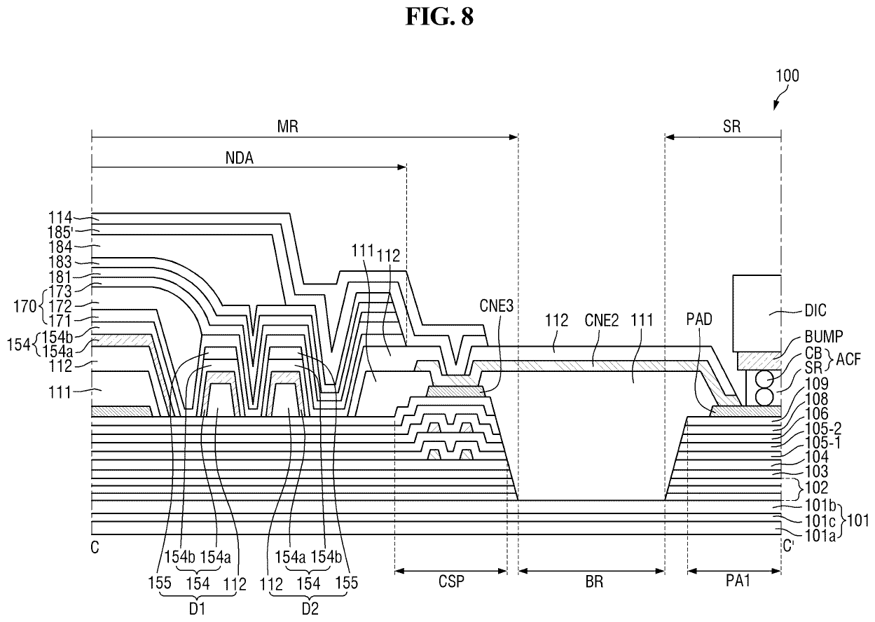

FIG. 8 is a cross-sectional view along line C-C′ in FIG. 1.

Referring to FIGS. 3, 7, and 8, the bending region BR can be disposed between the sub-region SR and the crack sensing pattern CSP. In the bending region BR, the panel inorganic layers 102, 103, 104, 105, 106, 107, and 109 can be removed to expose the upper surface of the substrate 101.

In the first pad area PA1, a pad electrode PAD disposed on the same layer as the first source electrode 121 (see FIG. 3) can be disposed, and a third connection electrode CNE3 disposed on the same layer as the first source electrode 121 (see FIG. 3) can be disposed on the crack sensing pattern CSP.

The first protective layer 111 can be disposed on the pad electrode PAD and the third connection electrode CNE3. The first protective layer 111 can be disposed in the bending region BR, and the first protective layer 111 can come into direct contact with the upper surface of the substrate 101 and in the bending region BR, the first protective layer 111 can come into direct contact with the side surfaces of the panel inorganic layers 102, 103, 104, 105, 106, 107, and 109.

A second connection electrode CNE2 can be disposed on the first protective layer 111, and the second connection electrode CNE2 can be disposed on the same layer as the connection electrode 145 (see FIG. 3). The second connection electrode CNE2 can electrically connect the pad electrode PAD to the third connection electrode CNE3. The second connection electrode CNE2 can be disposed on the bending region BR and can also be disposed on the first pad area PA1 and the crack sensing pattern CSP.

The data driving unit DIC can be disposed on the pad electrode PAD. The data driving unit DIC can include a bump BUMP, an anisotropic conductive film ACF can be disposed between the pad electrode PAD and the bump BUMP, and the anisotropic conductive film ACF can electrically connect the pad electrode PAD to the bump BUMP. The anisotropic conductive film ACF can include a resin SR and a plurality of conductive balls CB dispersed in the resin SR. The pad electrode PAD and the bump BUMP can be electrically connected through the conductive balls CB.

The second protective layer 112 can be disposed on the second connection electrode CNE2. The second protective layer 112 can expose the pad electrode PAD.

The first and second encapsulation layers 171 and 173 of the encapsulation part 170 can extend until before the bending region BR. For example, the first and second encapsulation layers 171 and 173 can extend until before the crack sensing pattern CSP, but the embodiments of the present disclosure are not limited thereto, and the first and second encapsulation layers 171 and 173 can also overlap the crack sensing pattern CSP. The first and second encapsulation layers 171 and 173 can be not disposed in the bending region BR.

The touch buffer layer 181 and the first touch insulation layer 183 can extend until before the bending region BR. For example, the touch buffer layer 181 and the first touch insulating layer 183 can extend until before the crack sensing pattern CSP, but the embodiments of the present disclosure are not limited thereto, and the touch buffer layer 181 and the first touch insulating layer 183 can also overlap the crack sensing pattern CSP. The touch buffer layer 181 and the first touch insulation layer 183 can be not disposed in the bending region BR.

The second touch insulating layer 184 can overlap the first dam D1 and the second dam D2. The second touch insulating layer 184 can be not disposed outside the second dam D2, but the embodiments of the present disclosure are not limited thereto.

A touch connection line 185′can be electrically connected to the second connection electrode CNE2. The touch connection line 185′can serve to provide a signal applied from the pad electrode PAD and the second connection electrode CNE2 to the first sensor electrode 185a or the second sensor electrode 185b described above in FIG. 3. The touch connection line 185′can be located on the same layer as the second touch conductive layer (the first sensor electrode 185a of FIG. 3), but the embodiments of the present disclosure are not limited thereto, and the touch connection line 185′can be located on the same layer as the first touch conductive layer (the bridge electrode 182 of FIG. 3) or formed of two first and second touch conductive layers, but the embodiments of the present disclosure are not limited thereto.

The filter insulating layer 114 can be disposed on the touch connection line 185′, and the filter insulating layer 114 can be not disposed in the bending region BR.

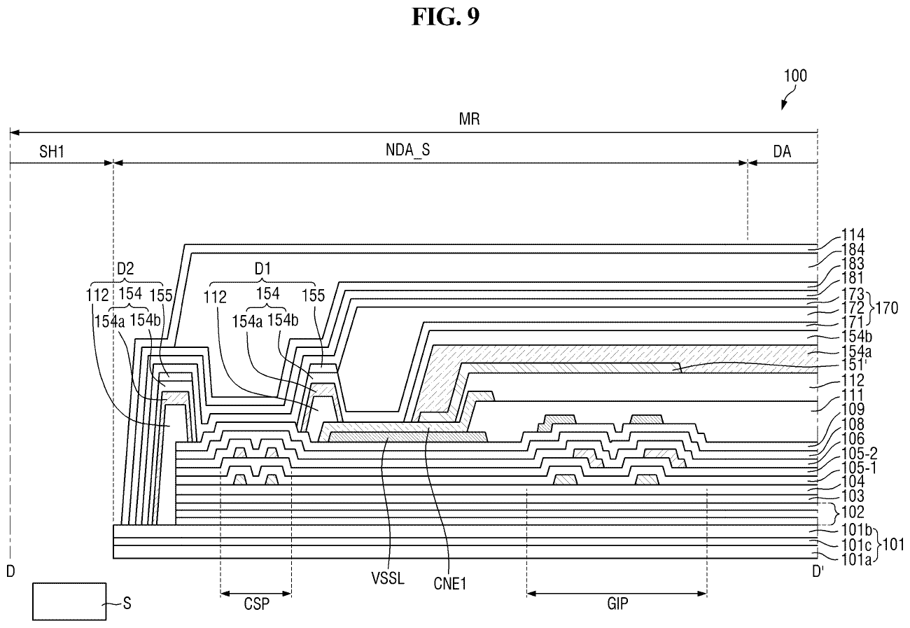

FIG. 9 is a cross-sectional view along line D-D′ in FIG. 1.

FIG. 9 illustrates a cross-sectional view of a periphery of a sensor non-display area NDA_S. Referring to FIG. 9, the display panel 100 can be not disposed in a first sensor hole SH1. For example, the first sensor hole SH1 can pass through both the substrate 101 of the display panel 100 and structures above the substrate 101. A sensor S can be disposed in the first sensor hole SH1. The sensor S can be an infrared sensor or a camera sensor, but the embodiments of the present disclosure are not limited thereto, and other sensors can be used.

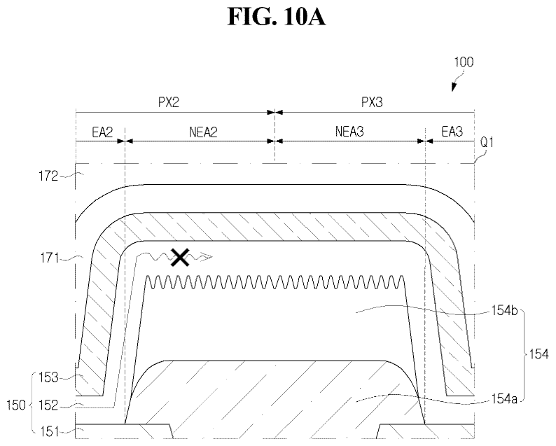

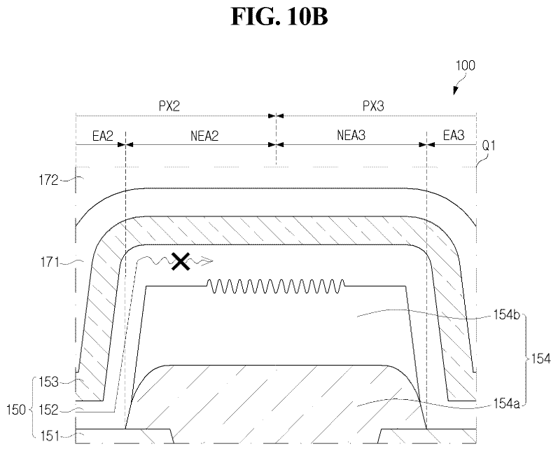

FIG. 10A is an enlarged cross-sectional view of area Q1 in FIG. 3.

Referring to FIG. 10A, a surface unevenness (or surface irregularities) having a surface roughness can be formed on the surface of the second bank 154b of the display panel 100 according to one embodiment. The surface roughness of the surface unevenness of the second bank 154b can be greater than the surface roughness of the surface unevenness of the first bank 154a. By forming a surface unevenness on the surface of the second bank 154b, it is possible to minimize a lateral leakage current (LLC) through the organic layer 152 integrally formed across adjacent sub-pixels PX1, PX2, and PX3 (see FIG. 3). For example, a length of the organic layer 152 increases on the surface of the second bank 154b of the non-light-emitting areas NEA1, NEA2, and NEA3 (see FIG. 3) due to the surface unevenness, and when the length of the organic layer 152 increases, a current generated in the organic layer 152 of the light-emitting area EA1, EA2, or EA3 (see FIG. 3) of one sub-pixel PX1, PX2, or PX3 can be delayed or blocked from flowing to an adjacent sub-pixel PX1, PX2, or PX3. In various embodiments of the present disclosure, reference to a roughness of a surface, such as a surface roughness, can be a quantitative or qualitative characteristic of a surface being not smooth. Various ways of providing a quantitative or qualitative characteristic of the surface can be used in various embodiments of the present disclosure, such as a root mean square average of profile height deviations from a mean line, for example, but other ways can be used.

FIG. 10B is a cross-sectional view of a display panel according to a modified example.

Referring to FIG. 10B, the surface of the second bank 154b of the display panel 100 according to the modified example differs from the display panel 100 according to FIG. 10A in that the surface unevenness is formed on the central portion, but the surface unevenness can be not formed at an outer portion. Since the remaining parts have been described above in FIG. 10A, the detailed descriptions thereof will be omitted.

With further references to FIGS. 10A and 10B, a location of the surface unevenness can vary on an upper surface (or a top surface) of the second bank 154b. In addition to an example where the surface unevenness is formed on the central portion and not at the outer portion, other embodiments of the present disclosure can have the surface unevenness being formed on the outer portion and not on the central portion of the second bank 154b. On a portion of the second bank 154b that does not include the surface unevenness, the topography of the portion can be flat, generally flat, smooth or generally smooth. That is, the surface roughness of the portion of the second bank 154b that does not include the surface unevenness can be different from the surface roughness of a portion of the second bank 154b that does include the surface roughness. In various embodiments of the present disclosure, the surface roughness of the portion of the second bank 154b that does not include the surface unevenness can be less than the surface roughness of the portion of the second bank 154b that does include the surface unevenness.

Also, in various embodiments of the present disclosure, the portion of the second bank 154b that does not include the surface unevenness can be multiple and/or the portion of the second bank 154b that does include the surface unevenness can be multiple. For example, the second bank 154b can have one or more portions with the surface unevenness and/or one or more portions without the surface unevenness. In various embodiments of the present disclosure, the portions with the surface unevenness and the portions without the surface unevenness can alternate on the upper surface of the second bank 154b.

With reference to FIGS. 10A and 10B, peaks or summits of the surface unevenness and/or valleys of the surface unevenness can be based on the portion of second bank 154b that is without the surface unevenness (e.g., the generally flat or the generally smooth surface). For example, in FIG. 10B, the generally flat or smooth surface of the portion of second bank 154b that is without the surface unevenness is located between the peaks or summits and the valleys of the surface unevenness, but in other embodiments of the present disclosure, the surface unevenness can be all peaks or summits without valleys where the peak or summits of the surface unevenness all protrude from the generally flat or smooth surface of the portion of second bank 154b that is without the surface unevenness. In other embodiments of the present disclosure, the surface unevenness can be all valleys without the peaks or summits where the valleys are all recesses from the generally flat or smooth surface of the portion of second bank 154b that is without the surface unevenness. In other embodiments of the present disclosure, the upper surface of the second bank 154b can have a combination the peaks/summits, the valleys, and the generally flat or smooth surface. In this regard, a height of the spacer 155 can be different from the height of the peaks/summits of the surface unevenness. In various embodiments of the present disclosure, the height of the spacer 155 can be greater than the height of the peaks/summits of the surface unevenness.

In various embodiments of the present disclosure, an upper surface of the organic layer 152 located on the bank 154 can be smooth or flat, while a lower surface of the organic layer 152 on the bank 154 can include a surface unevenness. For example, the surface unevenness at the lower surface of the organic layer 152 can correspond to that of the bank 154, such as that of the second bank 154b, for example. In various examples of the present disclosure, a thickness of the organic layer 152 located on the bank 154 can vary along a width of the bank 154, but such is not required, and some or all portions of the organic layer 152 located on the bank 154 can have the same thickness.

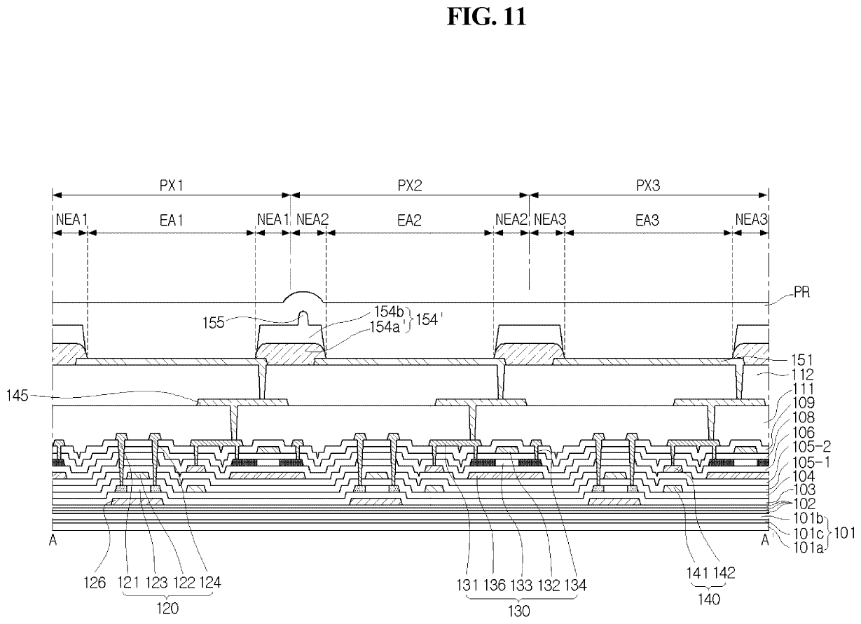

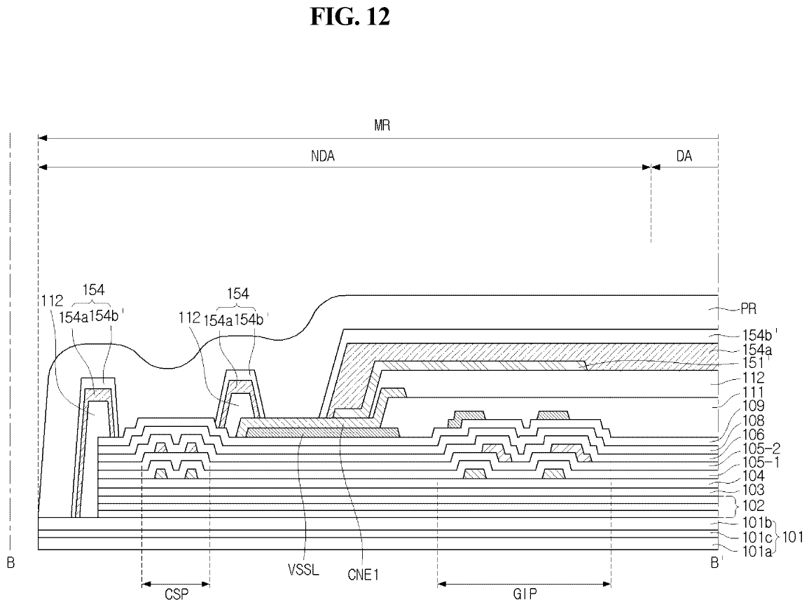

FIGS. 11 to 15 are cross-sectional views for each process of a method of manufacturing a display device according to one embodiment.

As illustrated in FIGS. 3, 10, 11, and 12, a bank 154′including the first bank 154a and a second bank 154b′ is formed, and the spacer 155 is formed on the bank 154′. The spacer 155 can be formed on the second bank 154b′, but in other embodiments of the present disclosure, the spacer 155 can be a result of a bump or a protrusion formed in the first bank 154a, which is subsequently covered or overlapped by the second bank 154b', but embodiments of the present disclosure are not limited thereto. For example, multiple spacers 155 can be provided in the bank 154′.

The bank 154′and the spacer 155 in the display area DA and the non-display area NDA are coated with a photoresist PR. The process of coating the bank 154′and the spacer 155 with the photoresist PR is to protect a mother panel when moving to a place in which the light-emitting element 150 of FIG. 3 is deposited on the mother panel on which the bank 154′and the spacer 155 are formed.

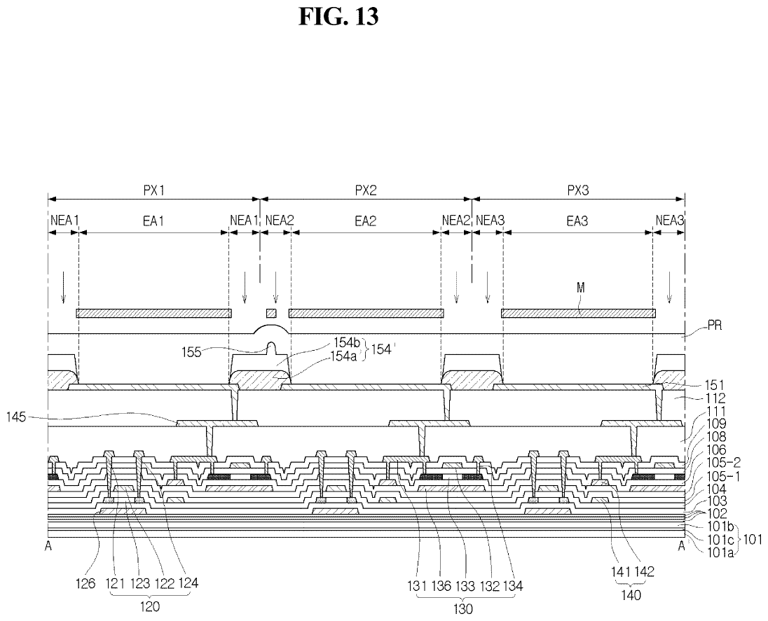

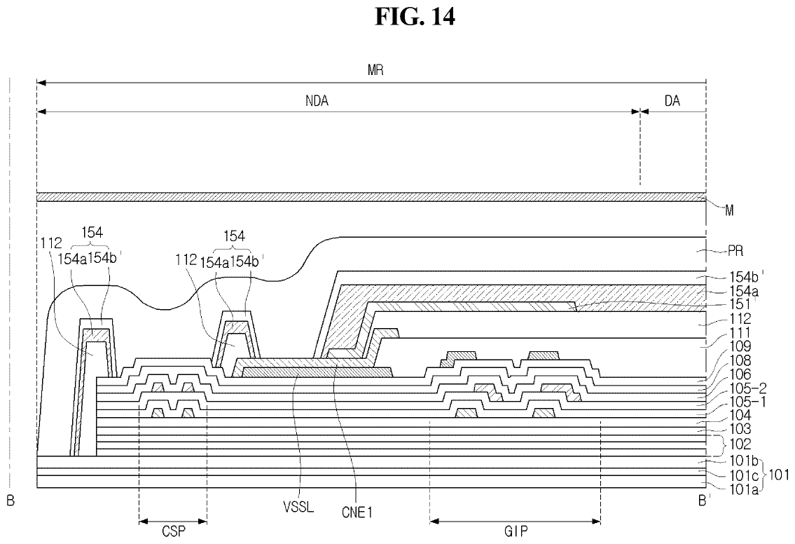

Subsequently, as illustrated in FIGS. 13 and 14, a mask M is disposed on the photoresist PR. The mask M can be disposed to cover the light-emitting areas EA1, EA2, and EA3 and the spacer 155 in the display area DA and to expose the remaining areas NEA1, NEA2, and NEA3. The mask M can cover the entirety of the non-display area NDA.

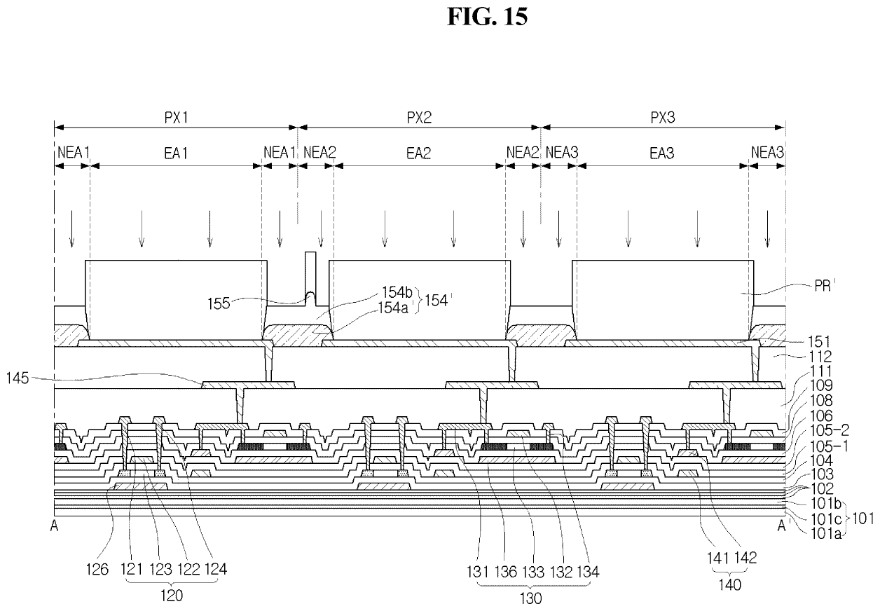

Subsequently, as illustrated in FIG. 15, the photoresist PR is patterned through the mask M. Accordingly, a photoresist PR of the area exposed by the mask M can be removed, and a photoresist PR of the area covered by the mask M can remain. Subsequently, an upper portion of the mask M is coated with a cleaning solution to clean (or remove) the photoresist PR. During the process of cleaning the photoresist PR, a surface unevenness can be formed on the surface of the second bank 154b on the area exposed by the photoresist PR (the non-light-emitting areas NEA1, NEA2, and NEA3 excluding the spacer 155).

Hereinafter, a display device according to other embodiments will be described. In the following embodiments, the detailed description of the reference numerals or components described in FIGS. 1 to 11 will be omitted, or the overlapping descriptions thereof will be omitted.

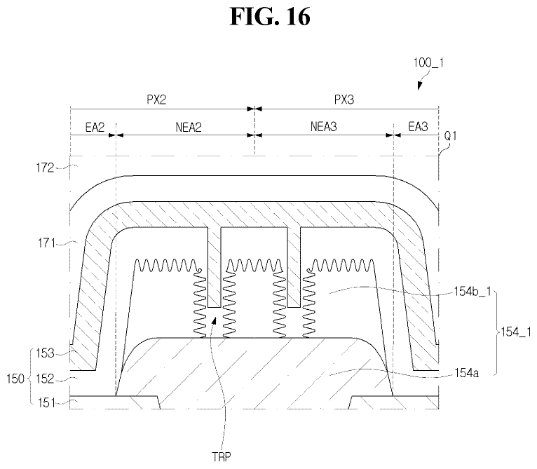

FIG. 16 is a cross-sectional view of a display device according to another embodiment.

Referring to FIG. 16, a bank 154_1 of a display panel 100_1 of the display device according to the present embodiment differs from the display panel 100 according to FIG. 10 in that a trench TRP is formed in a second bank 154b_1.

More specifically, the trench TRP can be formed in the second bank 154b_1, and the trench TRP can completely pass through from an upper surface (or a surface) to a lower surface of the second bank 154b_1. In the trench TRP, the upper surface (or the surface) of the first bank 154a can be exposed.

According to the present embodiment, since the bank 154_1 includes the trench TRP, the organic layer 152 formed integrally across the sub-pixels PX1, PX2, and PX3 (see FIG. 3) can be highly likely separated, thereby minimizing the lateral leakage current between the adjacent sub-pixels PX1, PX2, and PX3 (see FIG. 3).

The surface unevenness can also be formed on an inner surface of the second bank 154b 1 in contact with the trench TRP.

Since the remaining parts have been described above in FIGS. 3 and 10, the detailed descriptions thereof will be omitted below.

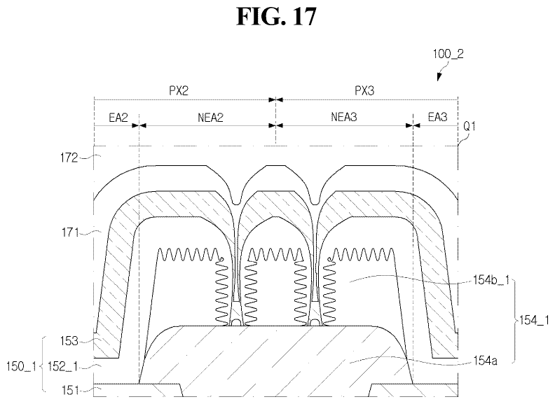

FIG. 17 is a cross-sectional view of a display device according to still another embodiment.

Referring to FIG. 17, a display panel 100_2 of the display device according to the present embodiment differs from the display panel 100_1 according to FIG. 16 in that the organic layer 152_1 of the light-emitting part 150_1 can be physically separated from the trench TRP.

According to the present embodiment, since the bank 154_1 includes the trench TRP, the organic layer 152_1 formed integrally across the sub-pixels PX1, PX2, and PX3 (see FIG. 3) can be separated, thereby minimizing the lateral leakage current between the adjacent sub-pixels PX1, PX2, and PX3 (see FIG. 3).

Since the remaining parts have been described above in FIG. 16, the detailed descriptions thereof will be omitted.

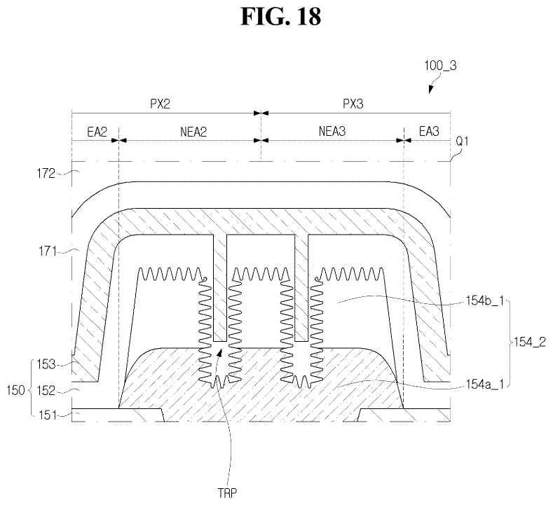

FIG. 18 is a cross-sectional view of a display device according to yet another embodiment.

Referring to FIG. 18, a display panel 100_3 of the display device according to the present embodiment differs from the display panel 100_1 according to FIG. 16 in that a surface of a first bank 154a_1 of a bank 154_2 can be recessed.

More specifically, the surface of the first bank 154a_1 can be recessed during the process of forming the trench TRP in the second bank 154b_1. For example, the trench TRP can be formed both in the second bank 154b_1 and in the first bank 154a_1.

A surface unevenness can be formed on both an inner surface of the second bank 154b_1 in contact with the trench TRP and an upper surface and inner surface of the first bank 154a_1, but embodiments of the present disclosure are not limited thereto. For example, the surface unevenness need not be formed in the inner surfaces of the first bank 154a_1 and/or the second bank 154b_1 so that the inner surfaces of the first bank 154a_1 and/or the second bank 154b_1 can generally be smooth, or the surface unevenness can be formed on one or more portions of the inner surfaces and/or the upper surfaces of the first bank 154a_1 and/or the second bank 154b_1.

Since the remaining parts have been described above in FIG. 16, the detailed descriptions thereof will be omitted.

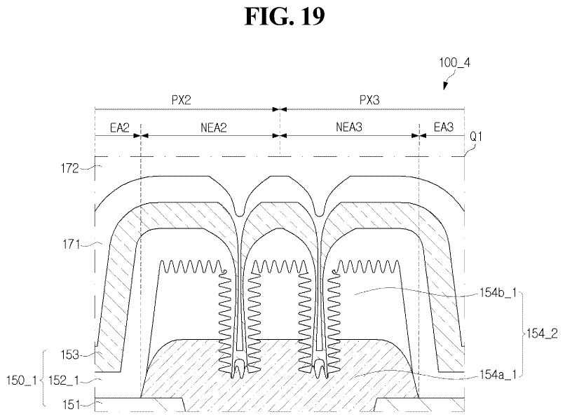

FIG. 19 is a cross-sectional view of a display device according to yet another embodiment.

Referring to FIG. 19, a display panel 100_4 of the display device according to the present embodiment differs from the display panel 100_3 according to FIG. 18 in that the organic layer 152_1 of the light-emitting part 150_1 can be physically separated from the trench TRP.

According to the present embodiment, since the bank 154_2 includes the trench TRP, the organic layer 152_1 formed integrally across the sub-pixels PX1, PX2, and PX3 (see FIG. 3) can be separated, thereby minimizing the lateral leakage current between the adjacent sub-pixels PX1, PX2, and PX3 (see FIG. 3).

Since the remaining parts have been described above in FIGS. 17 and 18, the detailed descriptions thereof will be omitted below.

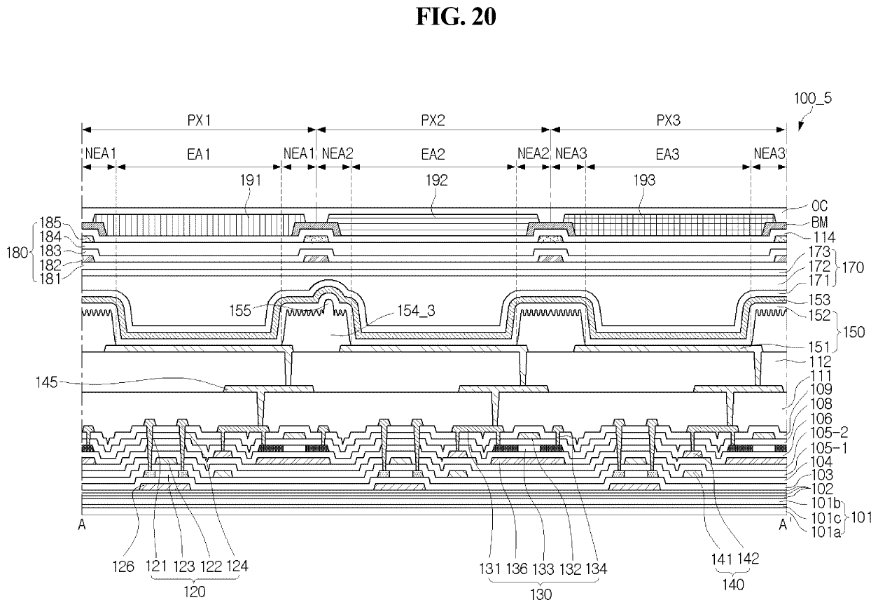

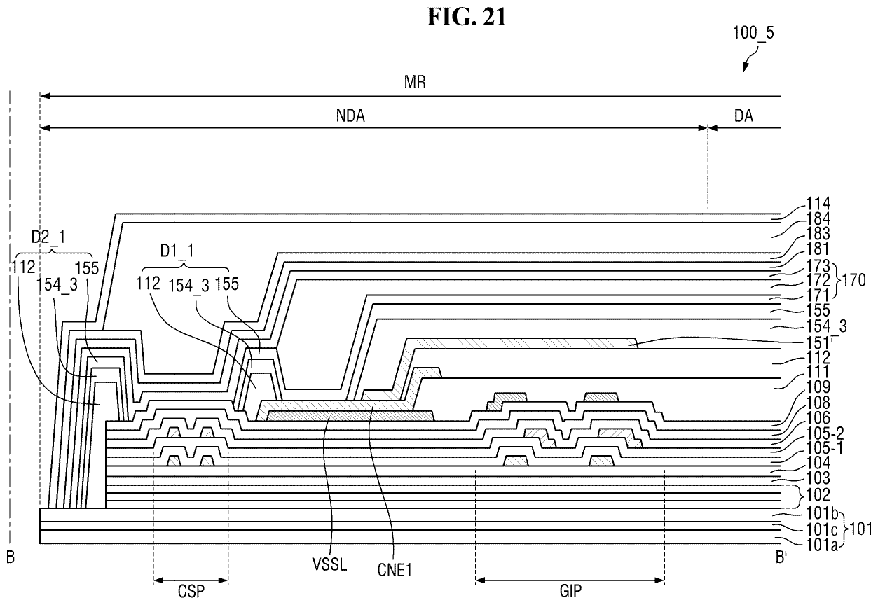

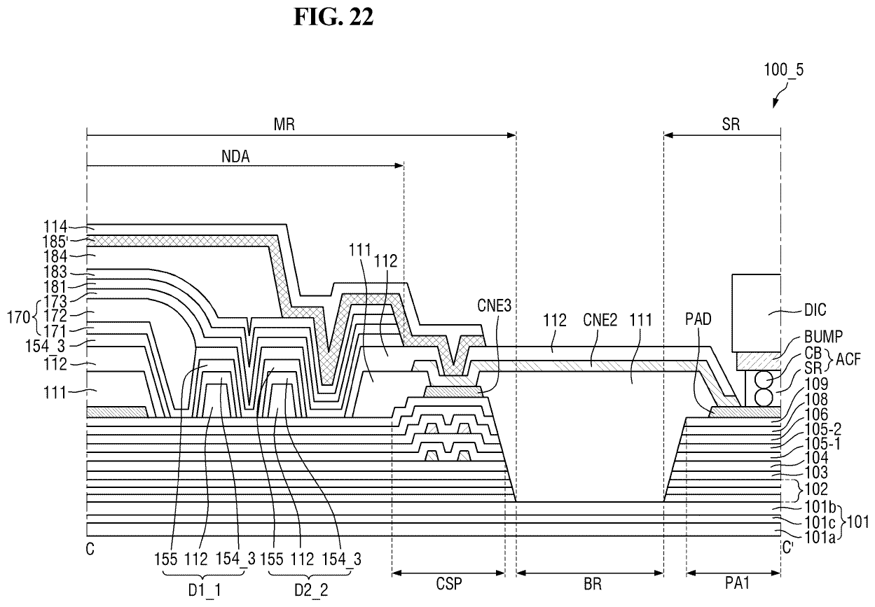

FIG. 20 is a cross-sectional view of a display device according to yet another embodiment. FIG. 21 is a cross-sectional view of the display device according to yet another embodiment. FIG. 22 is a cross-sectional view of the display device according to yet another embodiment.

Referring to FIGS. 20 to 22, a display panel 100_5 of the display device according to the present embodiment differs from the display panel 100 according to FIGS. 3, 7, and 8 in that it can include a bank 154_3.

More specifically, the bank 154_3 can be formed of a single layer. The bank 154_3 can include the same material as the second bank 154b of FIG. 3, but the embodiments of the present disclosure are not limited thereto. In some embodiments, the bank 154_3 can include the same material as the first bank 154a.

The spacer 155 can be formed of the same material as the bank 154_3, but the embodiments of the present disclosure are not limited thereto.

The surface unevenness can be formed on a surface of the bank 154_3.

As illustrated in FIGS. 21 and 22, the first layers of the first dam D1_1 and the second dam D2_1 can be formed as the bank 154_3, and the second layers thereof can be formed as the spacer 155, but the embodiments of the present disclosure are not limited thereto.

Since the remaining parts have been described above in FIG. 3, the detailed descriptions thereof will be omitted.

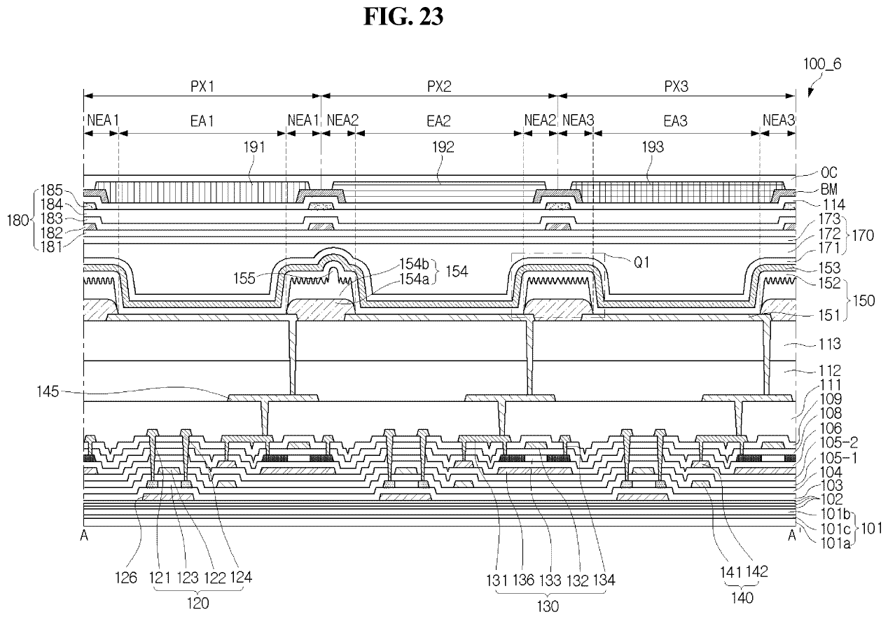

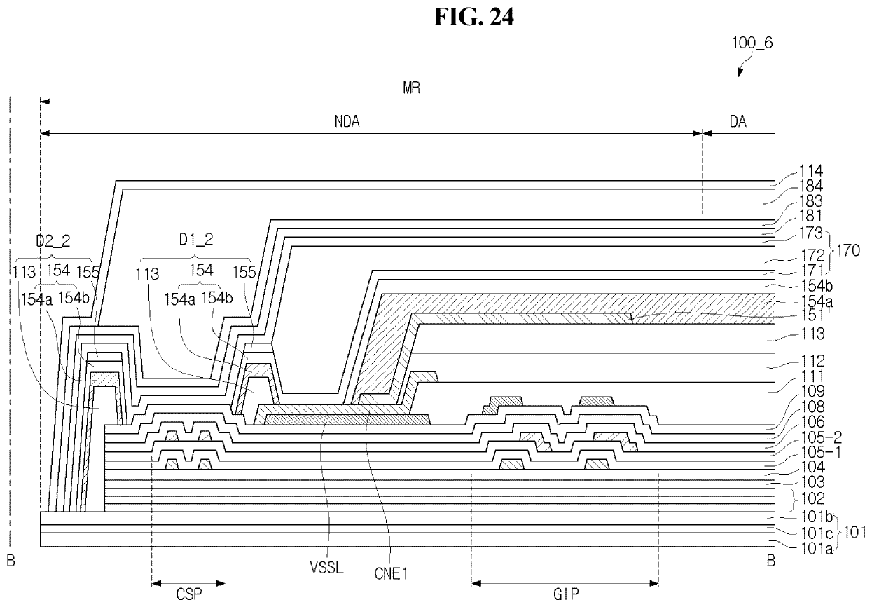

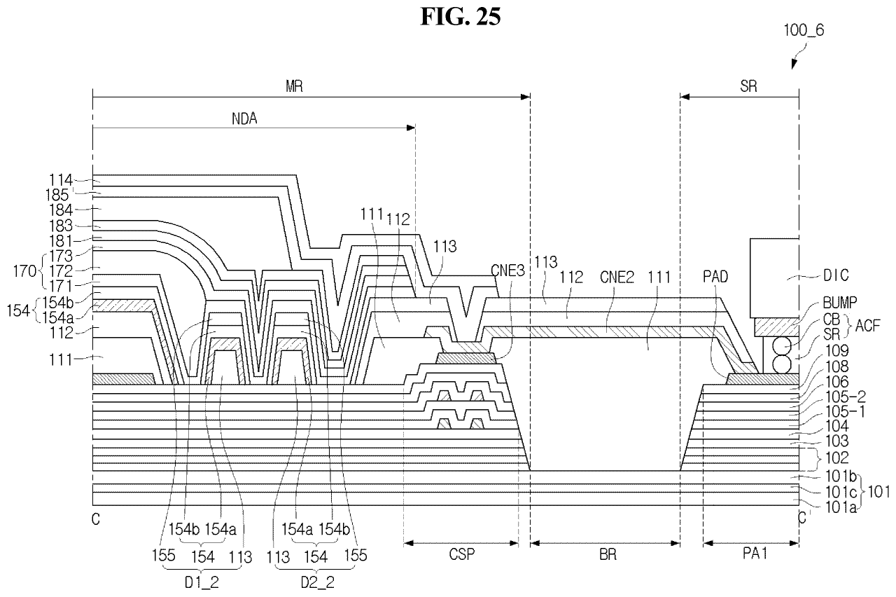

FIG. 23 is a cross-sectional view of a display device according to yet another embodiment of the present disclosure. FIG. 24 is a cross-sectional view of the display device according to yet another embodiment of the present disclosure. FIG. 25 is a cross-sectional view of the display device according to yet another embodiment of the present disclosure.

Referring to FIGS. 23 to 25, a display panel 100_6 of the display device according to the present embodiment differs from the display panel 100 according to FIGS. 3, 7, and 8 in that it can further include the third protective layer 113 on the second protective layer 112.

More specifically, the display panel 100_6 according to the present embodiment can further include the third protective layer 113 between the second protective layer 112 and the anode electrode 151. A material of the third protective layer 113 can include at least one of materials exemplified as the material of the second protective layer 112, but the embodiments of the present disclosure are not limited thereto.

As illustrated in FIGS. 24 and 25, each of a first dam D1_2 and a second dam D2_2 can include the third protective layer 113 as a first layer and need not include the second protective layer 112, but the embodiments of the present disclosure are not limited thereto.

Since the remaining parts have been described above in FIGS. 3, 7, and 8, the detailed descriptions thereof will be omitted below.

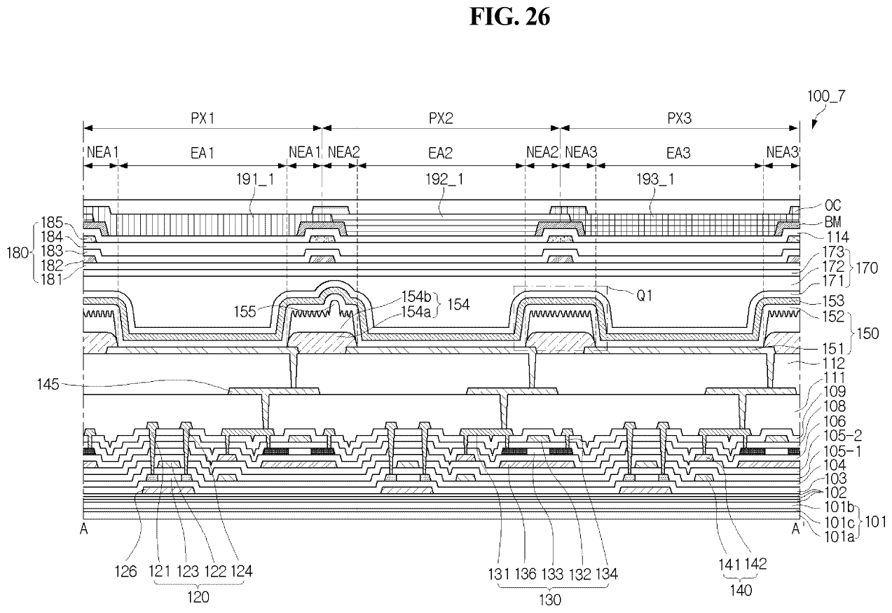

FIG. 26 is a cross-sectional view of a display device according to yet another embodiment of the present disclosure.

Referring to FIG. 26, color filters 191_1, 192_1, and 193_1 of a display panel 100_7 of the display device according to the present embodiment differ from the display panel 100 according to FIG. 3 in that they can overlap each other in the non-light-emitting areas NEA1, NEA2, and NEA3.

FIG. 26 illustrates that a second color filter 192_1 is located at the top, a first color filter 191_1 is located under the second color filter 192_1, and lastly a third color filter 193_1 is located at the bottom in each non-light-emitting area NEA1, NEA2, or NEA3, but the stacking order of each color filter 191_1, 192_1, or 193_1 in the non-light-emitting areas NEA1, NEA2, and NEA3 can vary according to a process order.

Since the remaining parts have been described above in FIG. 3, the detailed descriptions thereof will be omitted.

A display device according to various embodiments of the present disclosure can be described as follows.

According to one embodiment of the present disclosure, there is provided a display device including a substrate including a display area including a plurality of sub-pixels including a first sub-pixel, a second sub-pixel, and a third sub-pixel, and a non-display area around the display area, an anode electrode disposed in each of the sub-pixels on the substrate in the display area, a bank disposed on the anode electrode in the display area, located at a boundary between adjacent sub-pixels, and overlapping a periphery of an upper surface of the anode electrode, an organic layer disposed on the anode electrode and the bank in the display area and disposed across the plurality of sub-pixels, and a dam on the substrate in the non-display area, in which the dam includes the bank, and a surface unevenness is formed on an upper surface of the bank in the display area.

In the display device according to the embodiments of the present disclosure, a surface roughness of the bank in the display area can be greater than a surface roughness of the bank of the dam in the non-display area.

In the display device according to the embodiments of the present disclosure, a trench passing through the bank in a thickness direction can be formed on the bank in the display area, and the surface unevenness can be formed on an inner surface of the bank in the trench.

In the display device according to the embodiments of the present disclosure, the bank can include a first bank, and a second bank between the first bank and the organic layer.

In the display device according to the embodiments of the present disclosure, the first bank can include a black-based material, and the second bank can include a transparent-based material.

In the display device according to the embodiments of the present disclosure, a surface unevenness can be formed on an upper surface of the second bank.

In the display device according to the embodiments of the present disclosure, a trench passing through the second bank in a thickness direction can be formed in the second bank, and the surface unevenness can be formed on an inner surface of the second bank in the trench.

In the display device according to the embodiments of the present disclosure, the trench can pass through a part of the first bank, and the surface unevenness can be formed on a surface of the first bank in the trench.

In the display device according to the embodiments of the present disclosure, the organic layer can include a first light-emitting layer on the first sub-pixel, a second light-emitting layer on the second sub-pixel, and a third light-emitting layer on the third sub-pixel.

In the display device according to the embodiments of the present disclosure, in each sub-pixel, each of the first light-emitting layer, the second light-emitting layer, and the third light-emitting layer can be stacked in two or more layers.

The display device according to the embodiments of the present disclosure can further include a cathode electrode on the organic layer, and a black matrix located at the boundary between the adjacent sub-pixels on the cathode electrode, in which a width of the black matrix can be smaller than a width of the bank.

In the display device according to the embodiments of the present disclosure, an end of the black matrix can be closer to the boundary between the adjacent sub-pixels than an end of the bank.

The display device according to the embodiments of the present disclosure can further include a touch part on the cathode electrode, in which the touch part can include a bridge electrode, and a sensor electrode on the bridge electrode, and the black matrix can overlap the bridge electrode and the sensor electrode.

The display device according to the embodiments of the present disclosure can further include a color filter on the touch part and the black matrix, in which the color filter can include a first color filter on the first sub-pixel, a second color filter on the second sub-pixel, and a third color filter on the third sub-pixel.

In the display device according to the embodiments of the present disclosure, the first color filter, the second color filter, and the third color filter can overlap each other at the boundaries between the sub-pixels.

The display device according to the embodiments of the present disclosure can further include a first transistor between the substrate and the anode electrode, and a second transistor between the substrate or the first transistor and the anode electrode.

The display device according to the embodiments of the present disclosure can further include a first protective layer between the second transistor and the anode electrode, a first connection electrode disposed on the first protective layer, and a second protective layer on the first connection electrode, in which the first connection electrode can electrically connect the second transistor to the anode electrode.

In the display device according to the embodiments of the present disclosure, a semiconductor layer of the first transistor can include a polysilicon, and a semiconductor layer of the second transistor can include an oxide.

In the display device according to the embodiments of the present disclosure, the non-light-emitting area can include a low-potential voltage line, and a gate driving unit between the low-potential voltage line and the display area.

In the display device according to the embodiments of the present disclosure, the non-display area can further include a crack sensing pattern outside the low-potential voltage line, and the dam can overlap the low-potential voltage line.

In the display device according to the embodiments of the present disclosure, the bank can include the black-based material to absorb external light guided to the lower portion of the bank.

In the display device according to the embodiment of the present disclosure s, the organic layer is formed integrally across all of sub-pixels, but, by forming the surface unevenness on the surface of the bank, it is possible to minimize the lateral leakage current between adjacent sub-pixels.

In the display device according to the embodiments of the present disclosure, the organic layer is formed integrally across all of sub-pixels, but, by forming the surface unevenness on the surface of the bank and at the same time, forming the trench, it is possible to minimize the lateral leakage current between adjacent sub-pixels.

In the display device according to the embodiments of the present disclosure, due to a process, after the bank is formed, the surface unevenness is formed on the bank during the coating and cleaning process of the photoresist that is performed while the mother panel moves, thereby improving complexity of the process.

In the display device according to the embodiments of the present disclosure, by absorbing external light incident on the lower portion of the bank, it is possible to provide low-reflection display device.

However, effects obtainable from the present disclosure are not limited to the above-described effects, and other effects that are not mentioned will be able to be clearly understood by those skilled in the art to which the present disclosure pertains from the following description.

Although the embodiments of the present disclosure have been described above with reference to the accompanying drawings, those skilled in the art to which the present disclosure pertains will be able to understand that the above-described technical configuration of the present disclosure can be carried out in other specific forms without changing the technical spirit or essential features thereof. Accordingly, it should be understood that the above-described embodiments of the present disclosure are illustrative and not restrictive in all respects. In addition, the scope of the present disclosure is described by the claims to be described below rather than the detailed description. In addition, the meaning and scope of the claims and all changed or modified forms derived from the equivalent concept should be construed as being included in the scope of the present disclosure.

### DESCRIPTION OF REFERENCE NUMERALS

1: display device
100, 100_1, 100_2, 100_3, 100_4, 100_5, 100_6, 100_7: display panel
D1, D2: dam

What is claimed is:

1. A display device comprising:
a substrate including a display area including a plurality of sub-pixels, and a non-display area around the display area;
an anode electrode disposed in each of the plurality of sub-pixels on the substrate in the display area;
a bank disposed on the anode electrode of the display area, located at a boundary between adjacent sub-pixels, and overlapping a periphery of an upper surface of the anode electrode;
an organic layer disposed on the anode electrode and the bank in the display area and disposed across the plurality of sub-pixels; and
a dam on the substrate in the non-display area,
wherein the dam includes a same material as the bank, and
wherein a surface unevenness is formed on an upper surface of the bank in the display area.

2. The display device of claim 1, wherein a surface roughness of the surface unevenness of the bank in the display area is greater than a surface roughness of the surface unevenness of the bank of the dam in the non-display area.

3. The display device of claim 1, wherein a trench passing through the bank in a thickness direction of the bank is formed on the bank in the display area, and the surface unevenness is formed on an inner surface of the bank in the trench.

4. The display device of claim 1, wherein the bank includes a first bank, and a second bank between the first bank and the organic layer.

5. The display device of claim 4, wherein the first bank includes an opaque material, and the second bank includes a transparent material.

6. The display device of claim 4, wherein a surface unevenness is formed on an upper surface of the second bank.

7. The display device of claim 6, wherein a trench passing through the second bank in a thickness direction of the second bank is formed in the second bank, and the surface unevenness of the second bank is formed on an inner surface of the second bank in the trench.

8. The display device of claim 7, wherein the trench passes through a part of the first bank, and the surface unevenness is formed on a surface of the first bank in the trench.

9. The display device of claim 1, wherein the plurality of sub-pixels include a first sub-pixel, a second sub-pixel and a third sub-pixel, and
wherein the organic layer includes a first light-emitting layer on the first sub-pixel, a second light-emitting layer on the second sub-pixel, and a third light-emitting layer on the third sub-pixel.

10. The display device of claim 9, wherein, in each of the first sub-pixel, the second sub-pixel and the third sub-pixel, each of the first light-emitting layer, the second light-emitting layer, and the third light-emitting layer, respectively, is stacked in two or more layers.

11. The display device of claim 1, further comprising:
a cathode electrode on the organic layer; and
a black matrix located at the boundary between the adjacent sub-pixels of the plurality of sub-pixels on the cathode electrode,
wherein a width of the black matrix is smaller than a width of the bank.

12. The display device of claim 11, wherein an end of the black matrix is located closer to the boundary between the adjacent sub-pixels than to an end of the bank.

13. The display device of claim 11, further comprising a touch part on the cathode electrode,
wherein the touch part includes a bridge electrode, and a sensor electrode on the bridge electrode, and
wherein the black matrix overlaps the bridge electrode and the sensor electrode.

14. The display device of claim 13, further comprising a color filter on the touch part and the black matrix,
wherein the plurality of sub-pixels include a first sub-pixel, a second sub-pixel and a third sub-pixel, and
wherein the color filter includes a first color filter on the first sub-pixel, a second color filter on the second sub-pixel, and a third color filter on the third sub-pixel.

15. The display device of claim 14, wherein one of the first color filter, the second color filter, and the third color filter overlaps another of the first color filter, the second color filter, and the third color filter at the boundary between the adjacent sub-pixels.

16. The display device of claim 1, further comprising:
a first transistor between the substrate and the anode electrode; and
a second transistor between the substrate or the first transistor and the anode electrode.

17. The display device of claim 16, further comprising:
a first protective layer between the second transistor and the anode electrode;
a first connection electrode disposed on the first protective layer; and
a second protective layer on the first connection electrode,
wherein the first connection electrode electrically connects the second transistor to the anode electrode.

18. The display device of claim 16, wherein a semiconductor layer of the first transistor includes a polysilicon, and a semiconductor layer of the second transistor includes an oxide.

19. The display device of claim 1, wherein the non-display area includes:
a low-potential voltage line, and a gate driving unit between the low-potential voltage line and the display-area; or
a crack sensing pattern outside the low-potential voltage line, and the dam overlaps the low-potential voltage line.

20. A display device comprising:
a substrate including a display area including a plurality of sub-pixels;
an anode electrode disposed in the plurality of sub-pixels on the substrate in the display area;
a bank disposed on the anode electrode of the display area, located at a boundary between adjacent sub-pixels, and overlapping a periphery of an upper surface of the anode electrode;
an organic layer disposed on the anode electrode and the bank in the display area and disposed across the plurality of sub-pixels; and
wherein a surface unevenness is formed on a lower surface of the organic layer overlapping the bank.
